(19) United States
(12) Patent Application Publication
(10) Pub. No.: US 2026/0287281 A1
(43) Pub. Date: Sep. 24, 2026

(54) EQUALIZING FLOW MANIFOLD WITH BERNOULLI-DERIVED HIERARCHICAL GEOMETRY, ASYMMETRIC INLET/OUTLET ARCHITECTURES, AND MODULAR POLYGONAL FLOW UNITS, AND COOLING APPARATUS INCLUDING SAME

(71) Applicant: HRL Laboratories, LLC, Malibu, CA (US)

(72) Inventors: Adam Gross, Santa Monica, CA (US); Christopher Roper, Thousand Oaks, CA (US); David Smith, Newbury Park, CA (US); Jeremy Orosco, Canoga Park, CA (US)

(21) Appl. No.: 19/539,853

(22) Filed: Feb. 13, 2026

Related U.S. Application Data
(60) Provisional application No. 63/775,933, filed on Mar. 21, 2025.

(51) Int. Cl. F28F 9/02; B33Y 80/00; F28D 7/00; H05K 7/20

(52) U.S. Cl. CPC F28F 9/0263; F28D 7/0075; F28F 9/0268; H05K 7/20254; B33Y 80/00; F28F 2210/02; F28F 2215/00; F28F 2260/02

(57) ABSTRACT

A cooling apparatus includes a flow equalizing manifold having hierarchical flow levels with descending and ascending passages dimensioned according to Bernoulli-based design relations to maintain substantially uniform flow conditions along prescribed streamlines. In certain embodiments, stepped or linear ceilings vary passage cross-section to regulate velocity/pressure at branch interfaces feeding a microchannel array. The manifold can implement forked symmetry or prescribed asymmetry, including different numbers/geometries/levels for inlets versus outlets and elevated vapor outlets for two-phase operation. In further embodiments, modular polygonal (hexagonal/diamond) flow units at a final level provide passive, spatially distributed flow metering/collection. The manifold and an associated finned plate may be additively manufactured and configured as modular, removably coupled components.

### CROSS-REFERENCE TO RELATED APPLICATIONS

This application claims priority to and the benefit of U.S. Provisional Application No. 63/775,933, filed on Mar. 21, 2025, the entire content of which is incorporated herein by reference.

### BACKGROUND

### 1. Field

One or more aspects of embodiments of the present disclosure relate to a flow equalizing thermal management apparatus and cooling systems utilizing the thermal management apparatus. For example, the flow equalizing cooling thermal management apparatus utilizes Bernoulli principles and modular flow-balancing units with hexagonal and diamond-shaped geometries to maintain constant inflow and outflow conditions in microchannel cooling systems, and asymmetric inlet and outlet configurations to improve or optimize flow distribution, pressure balance, and liquid-vapor phase separation. The flow equalizing thermal management apparatus includes additively manufactured cooling blocks for efficient cooling of high-heat flux devices.

### 2. Description of Related Art

In existing high-performance cooling systems, particularly those involving microchannel arrays, the ability to consistently prescribe fluid flow behaviors is critical to achieving an optimal or suitable balance of flow efficiency and thermal performance. Comparable systems using flow manifolds often suffer from flow rate variability due to pressure gradients, turbulence, and geometric asymmetries. While some designs attempt to mitigate these issues through passive or active flow control, they often introduce complexity or inefficiency. For example, comparable flow manifolds use symmetric inlet and outlet designs, assuming substantially uniform flow requirements, but in applications including two-phase cooling and/or varying thermal loads symmetry may lead to flow imbalance, backpressure, or inefficient vapor-liquid separation. Comparable flow manifolds using hierarchical flow routing and symmetric geometries to distribute coolant across microchannel arrays may suffer from flow imbalance, pressure drop inefficiencies, and limited adaptability to non-substantially uniform heat loads or chiplet layouts.

The present disclosure improves upon these challenges by providing additively manufactured microchannel cooling blocks including flow equalizing manifolds that leverage fluid dynamics (e.g., Bernoulli's principle) to maintain constant flow characteristics, ideally within a symmetric geometry, but also operable in non-symmetric configurations. The flow equalizing manifolds of the present disclosure provide one or more suitable numbers and/or geometries (e.g., sizes) of inlets and outlets and hierarchical levels to accommodate variations in process needs and thermal loads and also provide modular manifold architectures that enable localized flow control, passive balancing, and geometric adaptability.

The following references are further provided and the entire contents of each of which are incorporated herein by reference:
D. B. Tuckerman and R. F. W. Pease, IEEE Electronic Device Letters, vol. EDL-2, no. 5, pp. 126-129 (1981).
M. A. Arie, et al., International Journal of Heat and Mass Transfer, vol. 81, pp. 478-489 (2015).
F. Yazici, et al., Examining the Uniformity of Flow Distribution in Manifolds, Journal of Applied Fluid Mechanics, 17(5), 989-1001 (2024).

The present disclosure is related to the following U.S. patent documents issued to HRL: U.S. Pat. No. 11,680,756, U.S. Patent Publication No. 2025/0071936, and U.S. patent application Ser. No. 19/332,898, the entire content of each of which is hereby incorporated by reference.

The preceding information disclosed in this Background section is only for enhancement of understanding of the background and related art of the disclosure and therefore it may contain information that does not constitute prior art.

### SUMMARY

One or more aspects of embodiments of the present disclosure are directed toward a microchannel cooling block including a flow equalizing manifold with features designed in accordance with Bernoulli flow theory to maintain constant inflow and outflow conditions across a microchannel array. The system is improved or optimized for forked symmetry that balances pressure and velocity profiles across the manifold, and also enables asymmetric configurations with constant flow behavior.

One or more aspects of embodiments of the present disclosure are directed toward a microchannel cooling block including a flow equalizing manifold with asymmetric inlet and outlet configurations. The number, geometry (e.g., size), and placement of inlets and outlets are independently enhanced to match the thermal and hydraulic process needs and thermal loads. The present disclosure includes designs with multiple small inlets and fewer large outlets, or vice versa, depending on the desired or suitable flow dynamics.

One or more aspects of embodiments of the present disclosure are directed toward a microchannel cooling block including a flow equalizing manifold with interconnected flow-balancing units arranged in hexagonal and diamond-shaped patterns. Each unit is configured to passively regulate flow using geometric constrictions and directional routing based on Bernoulli's principle. The hexagonal units form a tiling array that can conform to irregular chiplet layouts, while the diamond units serve as flow-splitting or merging nodes with predefined flow ratios (e.g., 1:1, 1:2). This architecture enables scalable, passive flow balancing and thermal optimization across complex cooling surfaces.

Additional aspects will be set forth in part in the description which follows and, in part, will be apparent from the description, or may be learned by practice of the presented embodiments of the disclosure.

One or more embodiments of the present disclosure provide a flow manifold for thermal management including: a primary plenum configured to receive or discharge a coolant; a plurality of hierarchical flow levels including: a top level having at least one inlet and a set of descending passages and at least one outlet and a set of ascending passages; at least one intermediate level having branching passages in fluid communication with the top level; and a final level including a tessellated array of hexagonal flow units and diamond-shaped flow units arranged between or adjacent to the hexagonal flow units, wherein the diamond-shaped flow units include internal constrictions and diverging channels dimensioned to split or merge fluid in a set ratio, and wherein a thickness or cross-sectional area of at least one of the hexagonal or diamond-shaped flow units varies laterally such that local cross-sectional area along a prescribed streamline varies according to Bernoulli's principle to maintain substantially constant local flow velocity and passively regulate flow distribution.

One or more embodiments of the present disclosure provide a flow equalizing manifold including: a top level including: at least one inlet configured for a liquid inflow and top descending (TD) passages in fluid communication with the inlet; and at least one outlet configured for a liquid discharge and top ascending (TA) passages in fluid communication with the outlet, a first hierarchical level including: first hierarchical descending (H1D) passages in fluid communication with the TD passages and having first descending liquid (1DL) streams; and first hierarchical ascending (H1A) passages in fluid communication with the TA passages and having first ascending liquid (1AL) streams, the H1D passages configured for the 1DL streams and the H1A passages configured for the 1AL streams, a final hierarchical level including: polygonal fluid passages including final hierarchical descending (HFD) polygonal passages and final hierarchical ascending (HFA) polygonal passages, the HFD polygonal passages in fluid communication with the H1D passages and having final descending liquid (FDL) streams, the HFD polygonal passages configured to provide first flow conditions to the FDL streams; and the HFA polygonal passages in fluid communication with the H1A passages and having final ascending liquid (FAL) streams, the HFA polygonal passages configured to provide second flow conditions to the FAL streams, wherein the first flow conditions and the second flow conditions include pressure and velocity.

In one or more embodiments, the polygonal fluid passages may be configured to passively regulate the first flow conditions and the second flow conditions according to Bernoulli's principle, and the first flow conditions may be substantially equal to or different than the second flow conditions.

In one or more embodiments, the polygonal fluid passages may include hexagonal fluid passages, tetragonal fluid passages, and any suitable combination thereof.

In one or more embodiments, the polygonal fluid passages may include a repeating configuration of the hexagonal fluid passages.

In one or more embodiments, the repeating configuration of the hexagonal fluid passages may further include tetragonal fluid passages, wherein the tetragonal fluid passages may be between two of the hexagonal fluid passages, at an inlet of a polygonal fluid passage, at an outlet of a polygonal fluid passage, and any suitable combination thereof.

In one or more embodiments, at least one of the hexagonal fluid passages and the tetragonal fluid passages may include flow channeling, flow guides, flow-splitting nodes, flow-merging nodes, and any suitable combination thereof, the flow channeling including flow constrictions, flow divergences, and any suitable combination thereof, the flow guides including posts, vanes, trusses, and any suitable combination thereof, and the flow-splitting nodes and the flow-merging nodes include flow ratios, the flow ratios independently selected from among 1:2 to 1:10 and 10:1 to 2:1.

In one or more embodiments, at least one of the hexagonal fluid passages and the tetragonal fluid passages may include flexible flow passages.

In one or more embodiments, the H1D passages may be greater in number than the TD passages, the H1A passages may be greater in number than the TA passages, the HFD polygonal passages may be greater in number than the H1D passages, the HFA polygonal passages may be greater in number than the H1A passages, the TD passages and the TA passages extend in an initial direction, the H1D passages and the H1A passages extend in a first direction, the first direction substantially perpendicular to and crossing the initial direction, and the HFD polygonal passages and the HFA polygonal passages extend in a final direction, the final direction substantially the same as the initial direction.

In one or more embodiments, flow equalizing manifold may further include at least one added hierarchical level.

In one or more embodiments, the flow equalizing manifold may be additively manufactured.

One or more embodiments of the present disclosure provide a cooling apparatus including the flow equalizing manifold of the present disclosure and a finned plate, wherein the final hierarchical level includes a bottom boundary, the finned plate includes a base plate, a microchannel array, and a top boundary, the top boundary being opposite to the bottom boundary, and each of the bottom boundary and the top boundary have a planar outer surface.

In one or more embodiments, the microchannel array may include fins and microchannels, the fins being connected to and extending from a surface of the base plate, each one of the microchannels being between each adjacent two of the fins, the microchannels being in fluid communication with the FDL streams and the FAL streams, and extending in a direction parallel to each other and perpendicular to the final direction of the HFD polygonal passages and the HFA polygonal passages.

In one or more embodiments, a bottom surface of the finned plate may be geometrically flexible and configured to conform to a non-planar surface, an irregularly shaped surface, and any suitable combination thereof.

In one or more embodiments, the flow equalizing manifold and the finned plate may be modular and removably coupled, and independently configured for a coolant fluid including a one-phase fluid being substantially vapor-free or a two-phase fluid being a liquid-vapor mixture.

One or more embodiments of the present disclosure provide a method of operating the cooling apparatus of the present disclosure, the method including: introducing the liquid inflow including a cool fluid to the inlet; flowing the FDL streams into the HFD polygonal passages and regulating the first flow conditions of the FDL streams, the FDL streams including the cool fluid; flowing the FDL streams into the microchannel array to provide microchannel flow streams having microchannel flow conditions; regulating the microchannel flow conditions; transferring energy to the microchannel flow streams to provide the FAL streams, the FAL streams including a warm fluid; and flowing the FAL streams into the HFA polygonal passages and regulating the second flow conditions of the FAL streams, the FAL streams including the warm fluid.

In one or more embodiments, the regulating of the first flow conditions, the second flow conditions, and the microchannel flow conditions may include passively regulating with the polygonal fluid passages according to Bernoulli's principle.

One or more embodiments of the present disclosure provide a method of making the cooling apparatus of the present disclosure, the method including: forming the flow equalizing manifold having the top, first hierarchical, and final hierarchical levels with descending passages and ascending passages; forming the finned plate having the microchannel array; and coupling the flow equalizing manifold to the finned plate.

One or more embodiments of the present disclosure provide a cooling system including: at least one cooling apparatus including the cooling apparatus of the present disclosure; at least one pump configured to circulate a coolant; at least one heat exchanger in fluid communication with the flow equalizing manifold of the cooling apparatus; an electronic component, the cooling apparatus on the electronic component; and a heat exchanger in fluid communication with the flow equalizing manifold of the cooling apparatus.

One or more embodiments of the present disclosure provide a data center including: a plurality of electronic components; and at least one cooling system including the cooling system of the present disclosure; wherein the plurality of cooling apparatuses are on the plurality of electronic components.

In one or more embodiments, a manifold is dimensioned such that, along a prescribed streamline, a deliberately varied cross-section (via stepped or linear ceilings) maintains a local velocity within a selected tolerance (e.g., within about ±5-10%) across corresponding branch interfaces, thereby reducing entry/exit pressure non-uniformity at microchannel junctions without active control.

In one or more two-phase embodiments, ascending vapor passages are preferentially sized (larger average hydraulic diameter than corresponding liquid return and descending passages within a common level) and vertically biased so at least one vapor outlet resides above a liquid outlet, promoting phase separation and damping flow instabilities.

### BRIEF DESCRIPTION OF THE DRAWINGS

The features and advantages of embodiments of the present disclosure will be better understood by reference to the following detailed description if (e.g., when) considered in conjunction with the accompanying drawings.

FIG. 1 is a schematic perspective view of a cooling apparatus including a flow equalizing manifold according to one or more embodiments of the present disclosure.

FIG. 2 is a schematic perspective view of a top descending passage of the cooling apparatus of FIG. 1.

FIG. 3 is schematic views of stepped tapered ceilings in passages according to one or more embodiments of the present disclosure.

FIG. 4 is schematic views of linear tapered ceilings in passages according to one or more embodiments of the present disclosure.

FIG. 5A is a schematic view of a finned plate including a base plate and a microchannel array according to one or more embodiments of the present disclosure.

FIG. 5B is an expanded view of area 5B of FIG. 5A.

FIG. 6A is a perspective view of a final hierarchical level of a flow equalizing manifold and an upper portion of a microchannel array according to one or more embodiments of the present disclosure.

FIG. 6B is an expanded cross-sectional view of a microchannel according to one or more embodiments of the present disclosure.

FIGS. 7A-7C are plan views of polygonal fluid passages according to one or more embodiments of the present disclosure.

FIG. 8 is a schematic view of a flow equalizing manifold according to one or more embodiments of the present disclosure.

FIG. 9 is a schematic view of a flow equalizing manifold according to one or more embodiments of the present disclosure.

FIG. 10 is a schematic view of a flow equalizing manifold according to one or more embodiments of the present disclosure.

### DETAILED DESCRIPTION

The following description sets forth one or more suitable example embodiments and details in order to provide a more thorough understanding of the present disclosure. However, the subject matter of the present disclosure may be embodied in many different forms, and is not limited to the embodiments and details set forth herein. All disclosed features may be replaced with comparable features serving the same, equivalent, or similar purpose, unless expressly stated otherwise. Features of one or more embodiments may be incorporated into other embodiments unless expressly stated otherwise.

In the drawings, the same or similar reference numerals refer to the same or similar elements throughout, and duplicative descriptions thereof may not be provided. The drawings are not necessarily drawn to scale, and thicknesses and dimensions of elements may be exaggerated for clarity.

Unless otherwise defined, all chemical names, technical and scientific terms, and terms defined in common dictionaries should be interpreted as having meanings consistent with the context of the related art and should not be interpreted in an ideal or overly formal sense.

As utilized herein, expressions such as “at least one of,” “one of,” “at least one selected from among,” and “selected from among,” if (e.g., when) preceding a list of elements, modify the entire list of elements and do not modify the individual elements of the list. As utilized herein, the expressions “at least one of A, B, or C”, “one of A, B, C, or a combination thereof” and “one of A, B, C, and a combination thereof” refer to each component and a combination thereof (e.g., A; B; A and B; A and C; B and C; or A, B, and C). For example, “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As utilized herein, it is to be understood that the terms such as “including,” “includes,” “include,” “having,” “has,” “have,” “comprises,” “comprise,” and/or “comprising” are intended to indicate the existence of the features, numbers, steps, actions, components, parts, ingredients, materials, and/or one or more (e.g., any suitable) combinations thereof disclosed in the specification and are not intended to preclude the possibility that one or more other features, numbers, steps, actions, components, parts, ingredients, materials, and/or one or more (e.g., any suitable) combinations thereof may exist or may be added. The term “combination thereof may include a mixture, a laminate, a complex, a copolymer, an alloy, a blend, a reactant of constituents.

As utilized herein, singular forms such as “a,” “an,” and “the” are intended to include the plural forms as well, unless the context clearly indicates otherwise.

As utilized herein, the terms “use,” “using,” and “used” may be considered synonymous with the terms “utilize/utilization,” “utilizing,” and “utilized,” respectively.

In this context, “consisting essentially of” refers to that any additional components will not materially affect the chemical, physical, optical or electrical properties of a claim element.

Furthermore, any claim element that does not explicitly recite a “means for” or “step for” in performing a function, is not to be interpreted as a “means” or “step” clause under 35 U.S.C. § 112(f). The use of “step of” or “act of” in the claims herein is not intended to invoke the provisions of 35 U.S.C. § 112(f).

It will be understood that if (e.g., when) an element (e.g., layer) is referred to as being “outside,” “inside,” “on,” “above,” “below,” “connected to,” or “coupled to” another element, it may be in direct contact with the other element, or one or more intervening elements may be present. In contrast, if (e.g., when) an element (e.g., layer) is referred to as being “directly” on, above, below, and/or the like. another element, no intervening elements are present. Terms describing spatial relationships between elements or features (such as “below,” “lower,” “under,” “above,” “upper,” and/or the like) should be interpreted in the context of the device as a whole. For example, an element described as being “under” a second element could be alternatively described as being “above” the second element in an alternative orientation, if (e.g., when) such orientation is available.

Example embodiments of the present disclosure will be described with reference to the accompanying drawings. In the drawings, the same or similar reference numerals refer to the same or similar elements throughout, and duplicative descriptions thereof may not be provided the specification. The thickness of layers, films, panels, regions, and/or the like, are exaggerated for clarity. It will be understood that if (e.g., when) an element such as a layer, film, region, or substrate is referred to as being “on” another element, it can be directly on the other element or intervening element(s) may also be present. In contrast, if (e.g., when) an element is referred to as being “directly on” another element, there are no intervening elements present.

Herein, the use of the term “may,” if (e.g., when) describing embodiments of the present disclosure, refers to “one or more embodiments of the present disclosure.” In addition, the use of alternative language, such as “or,” if (e.g., when) describing embodiments of the present disclosure, refers to “one or more embodiments of the present disclosure” for each corresponding item listed. For example, “A or B” is construed to include A, B, A+B, and/or the like. Similarly, the term “and/or” includes any and all combinations of one or more of the associated listed items. The symbol “/” as utilized herein, may be interpreted as “and” or “or” according to the context. Also, the term “exemplary”, “preferred”, “preferable”, “preferably”, and/or the like is intended to refer to an example, embodiment, or illustration.

All references herein to “this system” “proposed system”, “innovative method”, “method”, “this circuit”, “this architecture”, “this”, and/or the like shall refer to one or more embodiments of present disclosure.

### INTRODUCTION

The present disclosure provides a flow equalizing manifold having multiscale hierarchically interlaced flow routing, that leverages the heat exchangers and manifolds in U.S. Pat. No. 11,680,756 and U.S. Patent Publication No. 2025/0071936, with the important innovations of Bernoulli-driven flow dynamics to maintain constant inflow and outflow conditions across a microchannel array and forked symmetry that balances pressure and velocity profiles across the manifold. The flow passages of the present disclosure include interconnected flow-balancing units arranged in hexagonal and diamond-shaped patterns. Each unit is configured to passively regulate flow using geometric constrictions and directional routing based on Bernoulli's principle. The hexagonal units form a tiling array that can conform to irregular chiplet layouts, while the diamond units serve as flow-splitting or merging nodes with predefined flow ratios. The flow passages and microchannels of the present disclosure include asymmetric inlet and outlet configurations. The number, geometry (e.g., size), and placement of inlets and outlets are independently enhanced to match the thermal and hydraulic process needs and thermal loads.

In terms of efficiency, an optimal, desired, or suitable design provides minimal or reduced amount of desired or required power input. Pressure drop is directly associated with this input power, and thus minimizing or reducing pressure drop is desirable.

In terms of performance, a reduced specific thermal resistance (i.e., inverse total heat transfer coefficient) enables the removal of large heat loads (typically in this case, multiple kilowatts) without a large rise in temperature across the heat transfer interface, and over relatively small areas (typically in this case, one kilowatt dissipated over less than three square centimeters). The thermal resistance of a single-phase liquid cooling block may include thermal resistance of solid conduction, thermal resistance of convection, thermal resistance of sensible heat gain, and/or thermal resistance of a thermal interface material between the heat source and the cooling block.

The present disclosure outperforms existing methods by providing highly efficient motivation of fluid through the cooling block, enabled by reduced or minimized recirculating paths through channels to reduce frictional pressure drop, multi-stage turbulence mitigation to reduce turbulent pressure drop, and symmetric hierarchical manifolding (inlet/outlet configuration) to improve flow/pressure distribution uniformity, reducing pressure drop extrema.

The present disclosure may be utilized in suitable applications where thermal management of high heat load (multiple kilowatts) and/or high heat flux (hundreds of watts per square centimeter) producing devices is desired or required under significant size, weight, and/or efficiency constraints. Commercial applications include but are not necessarily limited to: power electronics (power transistors, amplifiers, and/or the like), densely populated integrated circuits (ICs) used for computational tasks (CPUs and GPUs, in particular those used in AI datacenters), communications systems (radar, microwave, 5G, and/or the like), and high power laser applications (LIDAR), directed energy microwave systems, particle accelerator components (especially targets), aerothermal heating in high speed flight, fusion reactor walls and blankets, and radio detection and ranging (RADAR) systems.

The present disclosure is the combined result of rigorous physics-based design decisions and a long, substantial iterative “try and fail” development process. Although some work has been done previously investigating some aspects of efficient microchannel cooling blocks, most of these studies have considered theoretical extrapolations of the principles and thus were limited by a lack of iterative development. The preceding innovations, most of which are synergistic in their contribution to efficiency and/or performance, were not immediately obvious due to the need to combine theoretical investigations with the ground truth provided by lab testing and development. Many were arrived at only after the latter was addressed. The resulting validated performance demonstrates marketability toward thermal management of next-generation heat flux producing electronics beyond what was previously thought possible by microchannel cooling blocks.

According to one or more embodiments of the present disclosure, a cooling apparatus includes a flow equalizing manifold and a finned plate. The cooling apparatus may be a cooling block, e.g., a microchannel cooling block, as described in more detail herein.

Flow Equalizing Manifold with Plenum

According to one or more embodiments of the present disclosure, a flow equalizing manifold for thermal management is part of a cooling apparatus, such as a microchannel cooling block, and includes a primary plenum having an inlet side and an outlet side. The primary plenum is configured to receive or discharge a coolant and a plurality of hierarchical flow levels including a top level, at least one intermediate level, and a final level.

The top level may have at least one inlet passage and at least one outlet passage. In some embodiments, at least one vapor outlet passage may be positioned above at least one liquid outlet passage to facilitate vapor-liquid separation in a two-phase operation. In some embodiments, the least one inlet passage and/or at least one outlet passage may be in the top level, the at least one intermediate level, the final level, and combinations thereof. In some embodiments, the primary plenum is configured for one-phase operation.

The top level may have a set of descending passages and a set of ascending passages. In some embodiments, each passage may include a tapered or stepped ceiling dimensioned to vary in cross-sectional area along a prescribed streamline.

The flow equalizing manifold has an asymmetric configuration in which a number or a geometry of the at least one inlet passage differs from a number or a geometry of the at least one outlet passage, or a number of the plurality of hierarchical flow levels with the set of descending passages differs from a number of hierarchical levels with the set of ascending passages.

The at least one intermediate level may have branching passages in fluid communication with the top level.

The final level may have passages configured to interface with a microchannel array.

The final level may have a tessellated array of hexagonal flow units and diamond-shaped flow units arranged between or adjacent to the hexagonal flow units, and the diamond-shaped flow units may include internal constrictions and diverging channels dimensioned to split or merge fluid in a set ratio. A thickness or cross-sectional area of at least one of the hexagonal or diamond-shaped flow units may vary laterally such that local cross-sectional area along a prescribed streamline varies according to Bernoulli's principle to maintain substantially constant local flow velocity and passively regulate flow distribution.

The tapered or stepped ceiling of each descending and ascending passage may be dimensioned according to Bernoulli's principle to maintain substantially constant flow velocity (e.g., along a prescribed streamline), thereby equalizing pressure and/or velocity at multiple microchannel entry or exit points.

Bernoulli's principle is a statement of energy conservation for a steady, incompressible, and inviscid fluid, and describes how the pressure of a fluid decreases as its velocity increases, e.g., assuming there is no energy loss due to friction or turbulence. Bernoulli's principle is associated with a class of equations, the most common of which pertains to flows that are approximately isentropic, steady, and incompressible and where inertia dominates over viscous effects (e.g., “high Reynolds number flows”). The term “Bernoulli equation,” as used herein refers to Equation 1 shown below, but the present disclosure is not limited thereto. The Bernoulli equation of the present disclosure may include forms associated with unsteady flows, compressible flows, flows involving heat transfer, two-phase systems having an incompressible liquid phase and a compressible vapor phase, and/or the like.

$$P + \frac{1}{2} ρ {v}^{2} + ρ gh = constant \qquad Equation 1$$

P=pressure of the fluid
ρ=density of the fluid
v=velocity of the fluid
g=acceleration due to gravity
h=height above a reference point

The Bernoulli equation indicates that the sum of kinetic energy (pressure), potential energy (height), and kinetic energy (velocity) is approximately (substantially) constant at any point along a streamline, which is a line tangent to the velocity vector of the fluid at every point. For example, the Bernoulli equation indicates that the sum of static pressure energy (ρ), kinetic energy per unit volume (½ρv²), and potential energy per unit volume (μgh) remains approximately (substantially) constant along a streamline for steady, incompressible, inviscid flow. For example, the total mechanical energy of a fluid should remain constant along a streamline. For example, if a fluid speeds up (higher velocity), its pressure drops, and if the fluid slows down, its pressure increases. The inverse relationship of fluid velocity and pressure ensures that fluid flow remains constant across all flow passages and microchannels of the microchannel cooling block of the present disclosure, regardless of local resistance or geometric variations.

The flow equalizing manifold may exhibit forked symmetry wherein the flow passages, e.g., the descending and ascending passages, bifurcate into two mirrored sub-passages on either side of a central vertical plane. This configuration ensures that each microchannel of the microchannel cooling block receives or discharges fluid at the same velocity and pressure, minimizing or reducing thermal gradients and maximizing or increasing cooling efficiency. The forked symmetry may improve the degree of balance among pressure and velocity profiles across the flow equalizing manifold and the microchannel cooling block. The forked symmetry also reduces the impact of local flow disturbances, as the mirrored geometry passively balances pressure drops and flow resistance. This is particularly important in high-density microchannel arrays, where even minor flow imbalances can lead to significant temperature variations.

The forked symmetry may be about a central plane having a duplicate number, geometry (e.g., size), arrangement and/or the like of inlet and outlet passages, and/or a duplicate number, geometry (e.g., size), arrangement and/or the like of hierarchical levels. For example, as used herein and unless stated otherwise, “forked symmetry” denotes a manifold geometry mirror-symmetric about a plane that bisects the manifold and is generally parallel to the predominant flow direction of the top level. “Balancing reference” refers to that symmetry plane, relative to which total hydraulic volume and/or cross-sectional area of counterpart passages on either side are designed to be substantially equal (or intentionally unequal, in asymmetric embodiments) to achieve targeted pressure/velocity distribution.

The flow equalizing manifold may exhibit an asymmetric or non-symmetric configuration that incorporates Bernoulli-driven flow control with flow conditioning features that maintain near-constant flow characteristics, e.g., in the absence of geometric symmetry. The asymmetric or non-symmetric configuration may have a number, geometry (e.g., size), arrangement, and/or the like of the inlet passages different than that of the outlet passages, and/or a number, geometry (e.g., size), arrangement and/or the like that is different for each of the hierarchical levels.

The flow equalizing manifold may include flow conditioning features selected from among tapered channels, tapered sections, lofted transitions, baffles, variable cross-sections, and turbulence-reducing structures.

The flow equalizing manifold may include auxiliary features between two of the hierarchical flow levels, non-limiting examples of which include flow dividing ribs, wings, arrays of posts, arrays of tubes, truss structures, fins extending only from one side, and steps.

The flow equalizing manifold may include filtration selected from among mesh screens, porous materials, helical structures, vortex structures, and replaceable cartridges.

The flow passages, e.g., the descending and ascending passages, may include a converging and/or diverging inlet and/or outlet structures having a diamond pattern or a zig zag pattern.

The flow equalizing manifold may be fabricated by additive manufacturing to provide precise control of internal geometries and integration with a microchannel finplate of the microchannel cooling block. Materials used in the additive manufacturing process may include thermally insulating polymers, metals, or composites, as determined by the thermal and mechanical requirements of the system that includes the flow equalizing manifold. For example, the flow equalizing manifold may be operable in single-phase or two-phase cooling environments.

Flow Equalizing Manifold with Top Level

A flow equalizing manifold according to one or more embodiments may include at least one inlet configured for a cool liquid inflow into at least one inlet passage and at least one outlet configured for a warm liquid discharge from at least one outlet passage. In some embodiments, the at least one outlet may be at least one liquid outlet. Each of the at least one inlet passage and at least one liquid outlet passage independently has an inlet passage or outlet passage geometry (e.g., size), an inlet passage total number is represented by “IN,” and an outlet passage total number is represented by “LOT.” IN and LOT may each independently be an integer from 1 to 20 and LOT may be about equal to or different than IN. In some embodiments, the liquid outlet passage geometry (e.g., size) may be about equal to or different than the inlet passage geometry (e.g., size), e.g., each of the at least one liquid outlet passage geometry (e.g., size) may independently be about equal to or different than each of the at least one liquid inlet passage geometry (e.g., size).

In one or more embodiments, a top level of the flow equalizing manifold may include top descending (TD) passages within the at least one inlet passage in fluid communication with the inlet(s) through which the cool coolant stream flows downward and top ascending (TA) passages within the at least one outlet passage in fluid communication with the outlet(s) through which the warm liquid discharge flows upward. The cool coolant stream is described as flowing downward and the warm liquid discharge as flowing upward, but the present disclosure is not limited thereto. For example, the flow equalizing manifold may have a reverse configuration wherein the cool liquid coolant stream flows downward through the TA passages and the warm liquid discharge flows upward through the TD passages. In some embodiments, the TA passages may be referred to as top ascending liquid (TAL) passages.

The cool liquid inflow may be a coolant stream, such as a single-phase coolant, a two-phase coolant, or a combination thereof. The coolant stream may be a liquid coolant, but the present disclosure is not limited thereto. The coolant stream may include water, ethylene glycol, propylene glycol, oils, air, refrigerants, halocarbons, and/or one or more (e.g., any suitable) combinations thereof. The warm liquid discharge includes thermal energy absorbed by the coolant stream (e.g., from a component coupled to the cooling apparatus) and may be substantially vapor-free or may be a liquid-vapor mixture. The vapor discharge is produced as the coolant stream absorbs thermal energy and undergoes a phase change, to enhance or increase the efficiency of the cooling apparatus of the present disclosure. The vapor discharge may be substantially liquid-free or may be a liquid-vapor mixture. For example, the vapor discharge may be neat, e.g., greater than 99.9% liquid-free. References to “cool” and “warm” herein are for ease of explanation but are non-limiting, and these terms may be replaced by “first” and “second” without affecting the disclosure.

The TD passages may include shallow ends and intake ends near the at least one inlet. The TD passages may be in fluid communication with the at least one inlet and have tapered ceilings defined by an intake height at the intake end and a shallow height at the shallow end, the shallow height being less than the intake height. The TA passages may include shallow ends and output ends near the at least one outlet. The TA passages may be in fluid communication with the at least one outlet and have tapered ceilings defined by an output height at the output end and a shallow height at the shallow end, the shallow height being less than the output height.

The flow equalizing manifold includes a first hierarchical level below the top level and a final hierarchical level below the first hierarchical level. References to “below” and “above” herein are for ease of explanation but are non-limiting, and these terms may be replaced by “first” and “second” without affecting the disclosure. The hierarchical levels of the flow equalizing manifold have “hierarchically interlaced multiscale flow manifolding (HIMFM)” that denotes an arrangement of two or more manifolding levels (e.g., first/second/final) that are interlaced across different layers and scales such that discrete streams are progressively subdivided and/or laterally redistributed to deliver substantially uniform face velocity to corresponding passages while maintaining counterflow. “First” and “final” refer to positions along a manifolded flow path from an inlet (first) toward the center and from the center toward the outlet (final) and do not imply order of manufacture. “Second,” “third,” and/or the like, if (e.g., when) present, denote intermediate manifolding levels that feed or collect from finer or coarser levels. The phrases “open to” and “in fluid communication with” are equivalent phrases that refer to passages and/or the like through which a fluid can flow, directly or via intermediate manifolding. For example, fluid in the first hierarchical level communicates with fluid in the final hierarchical level and any intermediate hierarchical level(s).

In one or more embodiments, the number of passages in an “n+1” hierarchical level may be greater, less or the same as the number of passages in the “n” hierarchical level. It will be appreciated that a greater number of passages in an “n+1” hierarchical level compared an “n” hierarchical level refers to the construction and geometry of the hierarchical level and/or passages. In other words, the number of passages in a hierarchical level is not determined or selected by separators and/or dividers to the passages, where the separators and/or dividers may be introduced into the design (e.g., in CAD software) after the primary hierarchical passages are established in order to further discretize the flow to obtain beneficial flow properties such as reducing the hydraulic diameter and Reynolds number in order to suppress turbulence and mitigate pressure drop.

The size (e.g., geometry) of passages in an “n+1” hierarchical level may be less than the size (e.g., geometry) of passages in an “n” hierarchical level. In one or more embodiments, the size (e.g., geometry) of passages in an “n+1” hierarchical level may be the same as the size (e.g., geometry) of passages in an “n” hierarchical level. In one or more embodiments, the size (e.g., geometry) of passages in an “n+1” hierarchical level may be greater than the size (e.g., geometry) of passages in an “n” hierarchical level.

The flow equalizing manifold may have equal numbers of hierarchical levels with ascending passages and descending passages. In one or more embodiments, the number of hierarchical levels having ascending passages may be greater or less than the number of hierarchical levels having descending passages.

In some embodiments, the top level may be a top hierarchical level.

The first hierarchical level includes first hierarchical descending (H1D) passages in fluid communication with the TD passages (and/or inlet passages) and first hierarchical ascending (H1A) passages in fluid communication with the TA passages (and/or outlet passages). The number of H1D passages may be greater than, fewer than, or the same as the number of TD passages (and/or inlet passages) and the number of H1A passages may be greater than, fewer than, or the same as the number of TA passages (and/or outlet passages). A size (e.g., geometry) of TD passages (and/or inlet passages) may be greater than, less than, or the same as that of the H1D passages and a size (e.g., geometry) of the TA passages (and/or outlet passages) may be greater than, less than, or the same as that of the H1A passages. For example, the TD and TA passages (and/or inlet and outlet passages) may have a diameter, cross-sectional area, hydraulic area, hydraulic volume, and/or the like that is greater than, less than, or the same as that of the H1D passages and/or H1A passages. The passages of one hierarchical level may have a substantially equal diameter, cross-sectional area, hydraulic area, hydraulic volume, and/or the like. In some embodiments, the H1A passages may be referred to as first hierarchical ascending liquid (H1AL) passages.

The flow equalizing manifold has a geometry that provides regulation of flow conditions to improve or ensure flow uniformity of streams flowing through passages and microchannels of the cooling apparatus. The phrase “flow uniformity” refers to flowing streams having substantially constant flow conditions (e.g., flow characteristics), where flow conditions may be pressure, velocity, mass, and/or the like. For example, the tapered ceilings may independently be stepped or linear and the TD and TA passages include regions aligned with underlying hierarchical passages, the regions having different ceiling heights configured to regulate flow conditions. One TD region may be above one H1D passage and one TA region may be above one H1A passage.

The H1D passages include first descending liquid (1DL) streams and each H1D passage may be configured for one of the 1DL streams, and the H1A passages include first ascending liquid (1AL) streams and each H1A passage may be configured for one of the 1AL streams. The term “stream” as used herein refers to liquid and/or vapor flowing through passages of the flow equalizing manifold (e.g., 1DL streams and 1AL streams) and/or microchannels of the cooling apparatus. The 1DL streams and 1AL streams may have flow uniformity, e.g., each 1DL stream having a substantially equal pressure and substantially equal velocity, and each 1AL stream having a substantially equal pressure and substantially equal velocity. In one or more embodiments, the flow conditions of the streams may be determined by heights of the tapered ceilings, which have a large intake height at the intake end and a shallow height at the shallow end. For example, the ceiling heights may improve or ensure flow uniformity of pressure and velocity of the streams.

In one or more embodiments, the final hierarchical level includes descending passages that discharge liquid directly into a microchannel array and ascending passages that receive a warm liquid discharge generated within the microchannel array. For example, the final hierarchical level includes final hierarchical descending (HFD) passages in fluid communication with the H1D passages and final hierarchical ascending (HFA) passages in fluid communication with the H1A passages. The number of HFD passages may be greater than, fewer than, or the same as the number of H1D passages and the number of HFA passages may be greater than, fewer than, or the same as the number of H1A passages. A size (e.g., geometry) of H1D passages may be greater than, less than, or the same as that of the HFD passages, and a size (e.g., geometry) of the H1A passages may be greater than, less than, or the same as that of the HFA passages. For example, the H1D and H1A passages may have a diameter, cross-sectional area, hydraulic area, hydraulic volume, and/or the like that is greater than, less than, or the same as that of the HFD passages and/or HFA passages. In some embodiments, the HFA passages may be referred to as final hierarchical ascending liquid (HFAL) passages.

In one or more embodiments, the top level of the flow equalizing manifold may include the at least one inlet in fluid communication with the at least one inlet passage and/or TD passages, and the at least one liquid outlet in fluid communication with the at least one outlet passage and/or TAL passages, and each of a flow direction of the TD passages and a flow direction of the TAL passages relative to the one or more inlets and/or the one or more outlets is independently horizontal, vertical, angular, or any suitable combination thereof.

In one or more embodiments, the top level of the flow equalizing manifold may include the at least one inlet in fluid communication with the at least one inlet passage and/or TD passages, and the at least one liquid outlet in fluid communication with the H1AL passages, and a flow direction of the TD passages relative to the at least one inlet is independently horizontal, vertical, angular, or any suitable combination thereof.

In one or more embodiments, the flow equalizing manifold may be configured for two-phase coolant streams and may include at least one vapor outlet configured for a vapor discharge from at least one vapor outlet passage and having a vapor outlet passage geometry (e.g., size), a vapor outlet passage total number is represented by (VOT) and VOT may be an integer from 1 to 20.

In some embodiments, the at least one vapor outlet passage may be in the top level, the first hierarchical level, the final hierarchical level, or a combination thereof. For example, vapor outlet passage may be at an elevation of the flow equalizing manifold that is higher than (e.g., above) the liquid outlet passage. It will be appreciated, that locating the vapor outlet passage higher than (e.g., above) the liquid outlet passage may facilitate separation and removal of the vapor discharge, the liquid discharge, and coolant stream and enhance or increase the efficiency of the cooling apparatus.

A top level configured for two-phase coolant streams may include top ascending vapor (TAV) passages within the at least one vapor outlet passage, the first hierarchical level may include first hierarchical ascending vapor (H1AV) passages, and the final hierarchical level may include final hierarchical ascending vapor (HFAV) passages. In some embodiments, the at least one vapor outlet is in fluid communication with the at least one vapor outlet passage, the TAV passages, the H1AV passages, the HFAV passages, or a combination thereof.

The TD and TAL passages have a TD hydraulic volume and TAL hydraulic volume, respectively, and the TAV passages have a TAV hydraulic volume that may be greater than the TD and/or TAL hydraulic volumes, e.g., to accommodate the larger volume of the vapor discharge produced as the liquid coolant stream changes phase. The larger size (e.g., geometry) of the ascending vapor passages (e.g., TAV passages) maintains a lower pressure for the vapor as it flows through the flow equalizing manifold and facilitates separation and/or removal of the liquid discharge from the vapor discharge. In one or more embodiments, within a common hierarchical level, each ascending vapor passage may have a larger average hydraulic diameter than each of the corresponding descending and/or ascending liquid passages. In one or more embodiments, the TAV passages have a hydraulic volume that is less than or equal to the TD and/or TAL hydraulic volumes. In one or more embodiments, within a common hierarchical level, each ascending vapor passage may have a smaller or equal average hydraulic diameter than each of the corresponding descending and/or ascending liquid passages.

In some embodiments, the at least one vapor outlet may be in the top level and in fluid communication with the at least one vapor outlet passages and/or TAV passages. In some embodiments, the vapor outlet passage geometry (e.g., size) may be greater than the liquid outlet passage geometry (e.g., size), VOT may be greater than LOT, or a suitable combination thereof.

In one or more embodiments, within a given hierarchical level, ascending vapor passages (TAV/H1AV/HFAV) have a larger average hydraulic diameter than counterpart descending or liquid-return passages to reduce vapor backpressure and encourage vapor routing to elevated outlets, thereby maintaining a desired liquid fraction within microchannels and mitigating dry-out, but the present disclosure is not limited thereto.

The HFD passages may include final descending liquid (FDL) streams and each HFD passage may be configured for one of the FDL streams. The HFA passages may include final ascending liquid (FAL) streams and each HFA passage may be configured for one of the FAL streams. In some embodiments, each HFAL passage may be configured for one of the FAL streams. The flow uniformity, for example, includes each FDL stream having a substantially equal pressure and substantially equal velocity, and each FAL stream having a substantially equal pressure and substantially equal velocity.

In one or more embodiments, each of the at least one inlet passage and the at least one liquid outlet passage may independently be in the top level, the first hierarchical level, the final hierarchical level, or a combination thereof. The at least one inlet passage may be in fluid communication with the TD passages, the H1D passages, the HFD passages, or a combination thereof. The at least one liquid outlet passage may be in fluid communication with the TA passages, the TAL passages, the H1A passages, the H1AL passages, the HFA passages, the HFAL passages, or a combination thereof.

In one or more embodiments, each of the TD passages and the TAL passages may have first ends on a first end of the flow equalizing manifold, and second ends on a second end of the flow equalizing manifold. The first ends of the TD passages may be aligned with or offset from each other, the second ends of the TD passages may be aligned with or offset from each other, the first ends of the TAL passages are aligned with or offset from each other, and the second ends of the TAL passages are aligned with or offset from each other. If (e.g., when) the first ends of the TD passages are aligned with each other, they may be aligned with or offset from the first ends of the TAL passages, and aligned with or offset from the first end of the flow equalizing manifold. If (e.g., when) the first ends of the TD passages are offset from each other, they may be aligned with or offset from the first ends of the TAL passages, and aligned with or offset from the first end of the flow equalizing manifold. If (e.g., when) the first ends of the TAL passages are aligned with each other, they may be aligned with or offset from the first ends of the TD passages, and aligned with or offset from the first end of the flow equalizing manifold. If (e.g., when) the first ends of the TAL passages are offset from each other, they may be aligned with or offset from the first ends of the TD passages, and aligned with or offset from the first end of the flow equalizing manifold.

In one or more embodiments, the flow equalizing manifold according to one or more embodiments may include polygonal fluid passages in at least one hierarchical level, e.g., the top, first, or final hierarchical level, or an additional (e.g., second) hierarchical level. In one or more embodiments, the final hierarchical level includes final hierarchical descending (HFD) polygonal passages and final hierarchical ascending (HFA) polygonal passages. The HFD polygonal passages may be greater, fewer, or equal in number to, and in fluid communication with, the H1D passages and are configured to provide first flow conditions to the FDL streams. The HFA polygonal passages may be greater, fewer or equal in number to, and in fluid communication with, the H1A passages and are configured to provide second flow conditions to the FAL streams. The first and second flow conditions may include pressure and velocity and the first flow conditions may be substantially equal to the second flow conditions or different than the second flow conditions. For example, any (e.g., each) FDL stream may have first flow conditions about 5% less or about 5% more than each other, and any (e.g., each) FAL stream has second flow conditions being about 5% less or about 5% more than each other.

The polygonal fluid passages are configured to passively regulate the first and second flow conditions using geometric constrictions and directional routing according to Bernoulli's principle, as described in more detail herein. The polygonal fluid passages may be or include hexagonal fluid passages, tetragonal fluid passages, and any suitable combination thereof. For example, the HFD polygonal passages and the HFA polygonal passages may independently be or include hexagonal fluid passages and/or tetragonal fluid passages.

In one or more embodiments, the polygonal fluid passages may be or include a repeating configuration of hexagonal fluid passages and may be arranged in a tessellated pattern. The repeating configuration of the hexagonal fluid passages may include tetragonal fluid passages, and the tetragonal fluid passages may be arranged between two of the hexagonal fluid passages, at an inlet of a polygonal fluid passage, at an outlet of a polygonal fluid passage, and any suitable combination thereof.

In one or more embodiments, the array of repeating polygonal fluid passages includes a flow pixel array.

In one or more embodiments, at least one of the hexagonal fluid passages and/or at least one of the tetragonal fluid passages may include flow channeling, flow guides, flow-splitting nodes, flow-merging nodes, and any suitable combination thereof. The flow channeling may include flow constrictions, flow divergences, and any suitable combination thereof. The flow guides may include posts, vanes, trusses, and any suitable combination thereof. The flow-splitting nodes and the flow-merging nodes include flow ratios, the flow ratios independently selected from among 1:2 to 1:10 and 10:1 to 2:1. For example, the flow ratios may be determined or defined by the geometry of the polygonal fluid passages, e.g., a 1:2 split achieved via channel width or length.

In one or more embodiments, at least one of the hexagonal fluid passages and/or at least one of the tetragonal fluid passages may include flexible flow passages which are configured to adjust to changes in flow conditions, e.g., pressure. In some embodiments, the flexible flow passages may be self-improving or optimizing and may be configured to automatically to adjust to changes in flow conditions.

The flow equalizing manifold may include added hierarchical levels, such as a second, third, or a further hierarchical level. In one or more embodiments, the flow equalizing manifold may include a second hierarchical level, e.g., between the first hierarchical level and the final hierarchical level. The second hierarchical level includes second hierarchical descending (H2D) passages in fluid communication with the H1D and HFD passages, and second hierarchical ascending (H2A) passages in fluid communication with the H1A and HFA passages. The number of H2D passages may be greater, fewer, or equal in number to the H1D and/or HFD passages, and the number of H2A passages may be greater, fewer, or equal in number to the H1A and/or HFA passages. A size (e.g., geometry) of H2D passages may be greater, less, or equal to that of the HFD passages, and a size (e.g., geometry) of the H2A passages may be greater, less, or equal to that of the HFA passages. For example, the H2D and H2A passages may have a diameter, cross-sectional area, hydraulic area, hydraulic volume, and/or the like that is greater, less or equal to that of the HFD passages and/or HFA passages.

The TD and TA passages (and/or inlet and outlet passages) may extend in an initial direction and the H1D and H1A passages extend in a first direction. For example, the first direction may be substantially perpendicular to the initial direction, and may cross the initial direction. The HFD and HFA passages and HFD and HFA polygonal passages may extend in a final direction, which may be substantially equal to the initial direction, and may be substantially perpendicular to the first direction, and may cross the first direction. The H2D and H2A passages may extend in a second direction, which may be substantially perpendicular to the final direction, and may cross the final direction. In one or more embodiments, the “n+1” hierarchical level may contain passages that extend in a direction that is substantially perpendicular to the passages in the “n” hierarchical level, but the present disclosure is not limited thereto. In some embodiments, the “n+1” hierarchical level may contain passages that extend in a direction that may cross the direction of the passages in the “n” hierarchical level.

In certain embodiments, the polygonal (hexagonal and/or tetragonal/diamond) units are implemented in the final hierarchical level interfacing the microchannel array. In inflow regions the polygons are widest proximal to feed junctions and taper laterally to meter local injection into underlying microchannels; in outflow regions the polygons widen proximal to collection junctions to accommodate aggregated return flow, thereby reducing pressure loss and smoothing cross-manifold gradients.

### Example Cooling Apparatus 10

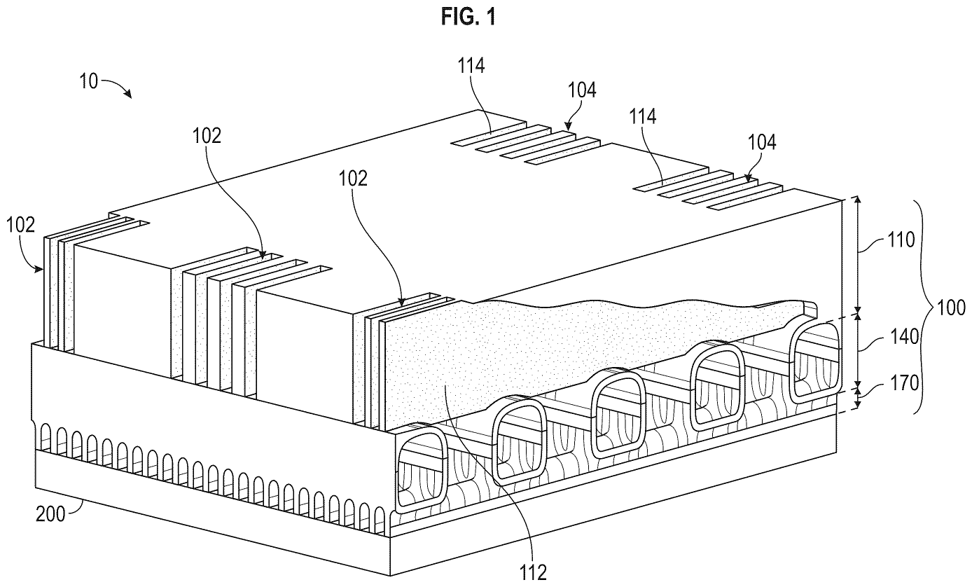

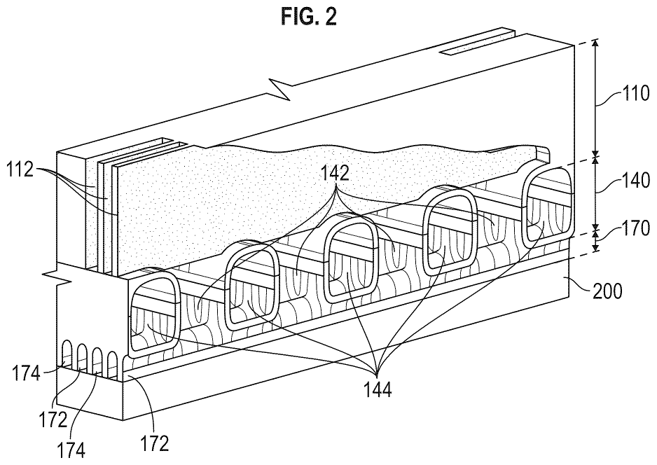

FIGS. 1 and 2 show a cooling apparatus 10 according to one or more embodiments of the present disclosure having a flow equalizing manifold 100 and a finned plate 200. A top level 110 of the flow equalizing manifold 100 includes inlet passages 102 for the coolant stream (e.g., cool liquid coolant) and liquid outlet passages 104 for the warm liquid discharge. Here, reference to “warm” and “cool” is only for ease of explanation, and terms can be replaced by “first” and “second” without affecting the disclosure.

FIG. 1 shows top level 110 including top descending (TD) passages 112 and top (TA) ascending passages 114. The TD passages and TA passages may be considered secondary passages to the inlet passages and outlet passages which are primary passages. Secondary passages are imposed by adding dividers after establishing the primary passages. Here, the inlet passages and outlet passages are discretized by dividers establishing TD passages and TA passages within the inlet passages and outlet passages, but the present disclosure is not limited thereto. A first hierarchical level 140 of flow equalizing manifold 100 includes first hierarchical descending (H1D) passages 142 having a hydraulic volume that may be less than that of the inlet passages 102 and/or TD passages 112, and first hierarchical ascending (H1A) passages 144 having a hydraulic volume that may be less than that of the outlet passages 104 and/or TA ascending passages 114. A final hierarchical level 170 of the of the flow equalizing manifold 100 includes final hierarchical descending (HFD) passages 172 having a hydraulic volume less than that of the H1D passages 142, and final hierarchical ascending (HFA) passages 174 having a hydraulic volume less than that of the H1A ascending passages 144.

A hierarchical level below another may have smaller and more passages to progressively partition the coolant streams as they flow from top level 110 to first level 140 to final level 170, but the present disclosure is not limited thereto. A hierarchical level above another may have larger and fewer passages to progressively coalesce the warm liquid discharge streams as they flow from final level 170 to first level 140 to top level 110, but the present disclosure is not limited thereto. In some embodiments, the coolant stream may be partitioned from top level 110 to final hierarchical level 170 directly and/or the liquid discharge may be coalesced from final hierarchical level 170 to top level 110 directly. A fluid impermeable barrier (e.g., solid material), between adjacent warm and cool fluid passages prevents mixing of warm and cool fluids. In some embodiments, final hierarchical level 170 separates the coolant stream to correspond well to microchannels in the finned plate 200 and coalesces a plurality of individual fluid flows from the microchannels into a single liquid discharge.

The flow equalizing manifold 100 illustrated in FIG. 1 includes 3 inlet passages 102, 2 outlet passages 104, 10 TD passages 112, 8 TA passages 114, 4 H1D passages 142, 5 H1A passages 144, 13 HFD passages 172, and 12 HFA passages 174, but the present disclosure is not limited thereto.

The number of inlet passages 102 and outlet passages 104 may independently be at least 1, e.g., about 1 to 20, 2 to 15, or 3 to 8. The number of TD and TA passages 112, 114 may independently be at least 1, e.g., 1 to 100, 2 to 80, 4 to 60, 6 to 30, or 8 to 20. The number of H1D and H1A passages 142, 144 may independently be at least 1, e.g., 1 to 300, 2 to 240, 4 to 180, 6 to 100, or 8 to 40. The number of HFD and HFA passages 172, 174 may independently be at least 1, e.g., 1 to 600, 2 to 540, 4 to 380, 6 to 260, or 8 to 100.

The number of TD passages 112 in each inlet passage 102 and the number of TA passages 114 in each outlet passage 104 may independently be the same or different. The number of H1D passages 142 and the number of H1A passages 144 in first hierarchical level 140 may be the same or different. The number of HFD passages 172 and the number of HFA passages 174 in final hierarchical level 170 may be the same or different.

The hydraulic volume of H1D passages 142 may be less than, greater than, or about the same as the hydraulic volume of the TD passages 112.

The hydraulic volume of H1A passages 144 may be less than, greater than, or about the same as the hydraulic volume of the TA passages 114.

The hydraulic volume of H1A passages 144 may be less than, greater than, or about the same as the hydraulic volume of the H1D passages 112.

The hydraulic volume of HFD passages 172 may be less than, greater than, or about the same as the hydraulic volume of the H1D passages 142.

The hydraulic volume of HFA passages 174 may be less than, greater than, or about the same as the hydraulic volume of the H1A passages 144.

The hydraulic volume of HFA passages 174 may be less than, greater than, or about the same as the hydraulic volume of the HFD passages 172.

In one or more of embodiments, HFD and HFA passages 172, 174 may independently have a smallest dimension (e.g., width) in a range of about 0.1 millimeter (mm) to about 1 centimeter (cm) or about 0.3 mm to about 5 mm.

As shown in FIG. 1, inlet passages 102 and outlet passages 104 are configured for input/output of flow in directions both (e.g., simultaneously) parallel and perpendicular to the direction of fluid flow through top level 110, but the present disclosure is not limited thereto. For example, inlet passages102 and outlet passages 104 may independently be configured for input/output of flow only parallel or only perpendicular to the direction of fluid flow through top level 110.

In some embodiments, are the inlet(s) and outlet(s) that provide cool liquid inflow and warm liquid discharge to the cooling apparatus 10. The inlet(s) and outlet(s) may be configured for input/output of flow in directions both (e.g., simultaneously) parallel and perpendicular to the direction of fluid flow through the top level 110. Other suitable arrangements of the inlet(s) and outlet(s) are contemplated, such an inlet(s) and outlet(s) extending at a 45° angle with respect to the direction of fluid flow, or inlet(s) and outlet(s) protruding (e.g., extending) above and/or below the flow equalizing manifold 100. In other embodiments, the inlet(s) and outlet(s) may extend in different suitable directions from each other and may be suitably varied to meet space requirements in a desired or suitable application (e.g., may be suitably designed to fit into a set or predetermined space). The inlet(s) and outlet(s) may independently include a flange, threaded opening, barbed connection, welded joint, and/or the like for fluid connection to a fluid handling system (e.g., an air conditioning system, a turbocharging system, radiator, heat exchanger, pumped fluid loop, and/or the like).

### Bernoulli's Equation

The flow conditions of the streams may be regulated according to Bernoulli's principle, e.g., the flow equalizing manifold may provide passive regulation of the flow conditions (e.g., passive flow regulation) according to Bernoulli's principle. The flow equalizing manifold 100, top level 110, inlet passages 102, outlet passages 104, TD passages 112, and TA passages 114 may have a geometry that maintains constant flow velocity and/or pressure (e.g., maintains flow uniformity) of the streams according to Bernoulli's principle. For example, the geometry may maintain flow uniformity of the 1DL, 1AL, FDL, and FAL streams and/or streams in the microchannels of the finned plate 200.

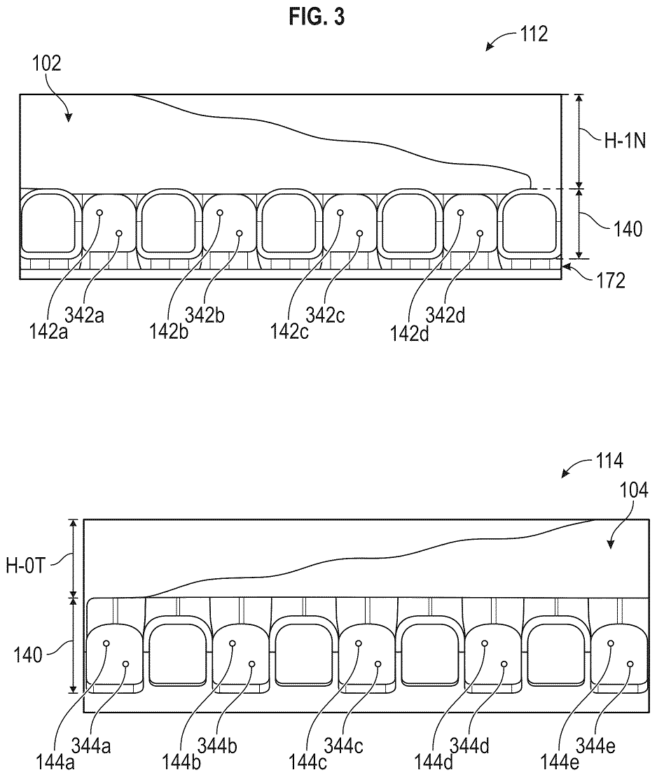

FIG. 3 is schematic view of TD and TA passages 112, 114. TD passage 112 includes four 1DL streams 342a, 342b, 342c, and 342d in four H1D passages 142a, 142b, 142c, and 142d. TA passage 114 includes five 1AL streams 344a, 344b, 344c, 344d, and 344e in five H1A passages 144a, 144b, 144c, 144d, and 144e. A Bernoulli equation describing regulation of flow conditions by the geometry of flow equalizing manifold 100 is shown in Equation 2.

$$ρ {v}_{1}^{2} + ρ g {h}_{1} + {p}_{1} = ρ {v}_{2}^{2} + ρ {gh}_{2} + {p}_{2} = … = ρ {v}_{N}^{2} + ρ {gh}_{N} + {p}_{N} \qquad Equation 2$$

v_{N} is the flow velocity at a point N.
h_{N} is the height of the point N.
p_{N} is the absolute pressure at the point N.
ρ is the fluid density.
g is the acceleration of gravity.
N is a non-zero integer from 1 to 1,000,000 for points corresponding (approximately) to the same streamline of fluids having a relatively high Reynolds number and are approximately isentropic, steady, and incompressible. To maintain an approximately equivalent pressure, the cross-sectional area of the flow passages may be varied to maintain constant flow velocity along the streamline. A cross-sectional area of the flow passages, as indicated by Equation 2, may be used to determine a ceiling height required to maintain constant flow velocity.

Accordingly, the ceiling profile (stepped or linear or a combination thereof) is selected such that, for a chosen streamline traversing sequential branch junctions, the local passage height h(N) produces a cross-sectional area A(N) that yields the target velocity profile v(N) via continuity (Q≈vA) while satisfying the intended Δp across each branch pair.

For TD passage 112 shown in FIG. 3, N is 4 and the 1DL streams 342a, 342b, 342c, and 342d are along a streamline. N is 1 for stream 342a and h₁ is the ceiling height of passage 342a. N is 2 for stream 342b and h₂ is the ceiling height of passage 342b. N is 3 for stream 342c and h₃ is the ceiling height of passage 342c. N is 4 for stream 342d and h₄ is the ceiling height of passage 342d.

For TA passage 114 shown in FIG. 3, N is 5 and the 1AL streams 344a, 344b, 344c, 344d, and 344e are along a streamline. N is 1 for stream 344a and h₁ is the ceiling height of passage 344a. N is 2 for stream 344b and h₂ is the ceiling height of passage 344b. N is 3 for stream 344c and h₃ is the ceiling height of passage 344c. N is 4 for stream 344d and h₄ is the ceiling height of passage 344d. N is 5 for stream 344e and h₅ is the ceiling height of passage 344e.

In one or more embodiments, the tapered ceiling of the TD and TA passages may be a stepped ceiling and the TD and TA passages include vertical steps. The number of vertical steps in a TD passage may be the same as the number of H1D passages, and the number of vertical steps in a TA passage may be the same as the number of H1A passages, but the present disclosure is not limited thereto. For example, a TD or TA passage may have a greater number of vertical steps or a lower number of vertical steps than the number of H1D or H1A passages. In one or more embodiments, the number of vertical steps in a TD or TA passage may be about 2 to about 5 times the number of H1D or H1A passages.

XD may be a number of H1D passages and a number of vertical steps in the stepped ceiling of the TD passages may be XD. XA may be a number of H1A passages and a number of steps in the stepped ceiling of the TA passages may be XA.

XD and XA may each independently be a non-zero integer from 1 to 100.

FIG. 3 shows that XD is 4 and XA is 5.

FIG. 3 shows that an intake height of the TD passages (H-IN) is a vertical distance between a top edge of the first hierarchical level and a top edge of the TD passages.

An average stepped ceiling height (H-INM) of the TD passages may be calculated as the intake height (H-IN) divided by the number of H1D passages (XD), e.g., H-INM=H-IN/XD. In some embodiments, H-INM may be about 2% to about 30%, or about 5% to about 15% of H-IN/XD. In some embodiments, an individual step height may vary from other step heights. An individual step height may be about 2% to about 30% or about 5% to about 15% from the average stepped ceiling height (H-INM).

A stepped ceiling height of an H1D passage may be a distance between the average stepped ceiling height (H-INM) and the intake height (H-IN), e.g., the H1D passage may have a stepped ceiling height between the values H-INM and H-IN.

FIG. 3 shows that an output height of the TA passages (H-OT) is a vertical distance between a top edge of the first hierarchical level and a top edge of the TA passages.

An average stepped ceiling height (H-OTM) of the TA passages may be calculated as the output height (H-OT) divided by the number of H1A passages (XA), e.g., H-OTM=H-OT/XA. In some embodiments, H-OTM may be about 2% to about 30%, or about 5% to about 15% of H-OT/XA. In some embodiments, an individual step height may vary from other step heights. An individual step height may be about 2% to about 30% or about 5% to about 15% from the average stepped ceiling heigh (H-OTM).

A stepped ceiling height of an H1A passage may be a distance between the average stepped ceiling height (H-OTM) and the output height (H-OT), e.g., the H1A passage may have a stepped ceiling height between the values H-OTM and H-OT.

In one or more embodiments, the stepped ceiling height of a TD or TA passage may be a distance between an average stepped ceiling height (H-INM or H-OTM) and the intake height (H-IN) or the output height (H-OT).

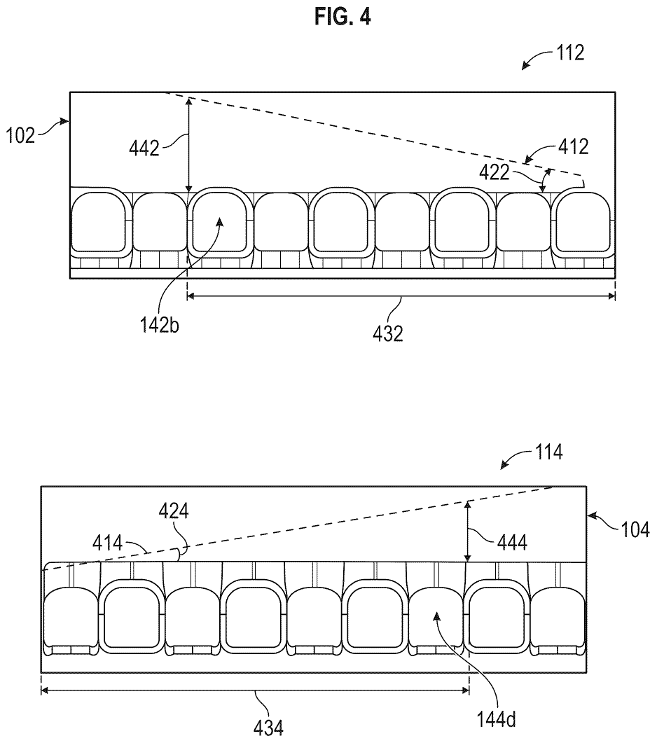

FIG. 4 shows schematic views of TD and TA passages 112, 114 having tapered ceilings that are linear ceilings 412 and 414, which may substantially be planes. LCA is an angle 422, 424 between a plane defined by a top edge of the first hierarchical level and the linear ceilings 412, 414. In one or more embodiments, LCA may be from about 1 degree (°) to about 45°.

FIG. 4 shows BSD 432 is a distance between the shallow end of the TD passage 112 and a location of an H1D passage (e.g., H1D passage 142b). A linear ceiling height 442 of the H1D passage may be calculated as “BSD 432 multiplied by the tangent of the angle LCA 422” (e.g., BSD×tan (LCA)). In some embodiments, the linear ceiling height 442 may be about 2% to about 30%, or about 5% to about 15% of BSD×tan (LCA).

FIG. 4 shows BSA 434 is a distance between the shallow end of the TA passage 114 and a location of an H1A passage (e.g., H1A passage 144d). A linear ceiling height 444 of the H1A passage may be calculated as “BSA 434 multiplied by the tangent of the angle LAC 424 (e.g., BSA×tan (LCA)). In some embodiments, the linear ceiling height 444 may be about 2% to about 30%, or about 5% to about 15% of BSA×tan (LCA).

In one or more embodiments, the linear ceiling height of a TD or TA passage may be a distance from the shallow end of the TD or TA passage multiplied by the tangent of the angle of the linear ceiling.

In one or more embodiments, the intake height (H-IN) of the tapered ceiling of the TD passages may be about 1 to about 25 millimeters (mm) and the shallow height of the tapered ceiling of the TD passages may be about 1% to about 99% less than the intake height.

In one or more embodiments, the output height (H-OT) of the tapered ceiling of the TA passages may be about 1 to about 25 mm, and the shallow height of the tapered ceiling of the TA passages may be about 1% to about 25% less than the output height.

In one or more embodiments, the intake/output heights (H-IN/H-OT) and shallow heights are selected based on intended branch counts (XD/XA), coolant properties, and allowable pressure differential such that along a prescribed streamline the resulting cross-sectional area profile yields the desired velocity uniformity tolerance without active control.

In one or more embodiments, the intake height (H-IN) of the tapered ceiling of the TD passages and the output height (H-OT) of the tapered ceiling of the TA passages are application-dependent and selected based on target branch counts (XD, XA), coolant properties, and allowable Δp; the shallow height is selected to be a fraction of H-IN or H-OT, respectively, sufficient to achieve the velocity uniformity tolerance along the intended streamline.

In one or more embodiments, the inlet, outlet, TD, TA, H1D, H2D, HFD, and HFA passages may independently include geometric regions configured to provide flow uniformity. These geometric regions may include flow conditioning features that maintain near-constant flow characteristics, e.g., in the absence of geometric symmetry. The geometric regions may include tapered channels, variable cross-sections, or turbulence-reducing structures. The geometric regions may maintain substantially equal flow conditions among a group of 1DL streams, a group of 1AL streams, a group of FDL streams, a group of FAL streams, and at least one group of streams in microchannels. For example, the H1D, H1A, HFD, and/or HFA passages may include geometric regions configured to provide substantially equal flow conditions to the 1DL, 1AL, FDL, and FAL streams, and/or streams in microchannels.

The flow equalizing manifold may have a forked symmetry that includes a balancing reference. For example, the balancing reference may be a plane of symmetry bisecting the flow equalizing manifold and an orientation of the plane of symmetry may be in a direction substantially parallel to a flow direction of the top level. In some embodiments, the plane of symmetry may be orientated in a direction substantially parallel to a flow direction of the inlet passages and/or TD passages. For example, a total volume of the liquid inflows and a total volume of the liquid discharges may be substantially equal with respect to the balancing reference. In one or more embodiments, a total volume (e.g., hydraulic volume), a total hydraulic area, and/or a total mass flow of the inlet passages and/or TD passages and a total volume (e.g., hydraulic volume), a total hydraulic area, and/or a total mass flow of the outlet passages and/or TA passages or the TAL passages may be substantially equal with respect to the balancing reference. In one or more embodiments, a total volume (e.g., hydraulic volume), a total hydraulic area, and/or a total mass flow of the inlet passages and/or TD passages and a total volume (e.g., hydraulic volume), a total hydraulic area, and/or a total mass flow of the outlet passages and/or TA passages or the TAL passages may be different with respect to the balancing reference.

The flow equalizing manifold may be asymmetric or non-symmetric and a total volume (e.g., hydraulic volume), a total hydraulic area, and/or a total mass flow of the liquid inflows and a total volume (e.g., hydraulic volume), a total hydraulic area, and/or a total mass flow of the liquid discharges may be substantially different with respect to the balancing reference. In one or more embodiments, a total volume (e.g., hydraulic volume), a total hydraulic area, and/or a total mass flow of the inlet passages and/or TD passages and a total volume (e.g., hydraulic volume), a total hydraulic area, and/or a total mass flow of the outlet passages and/or TA passages may be substantially different with respect to the balancing reference.

### Finned Plate

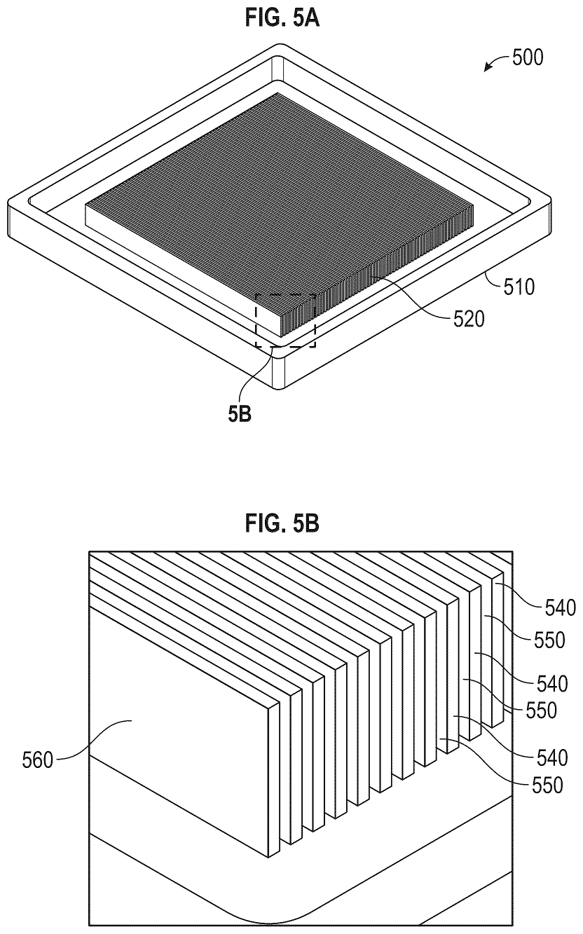

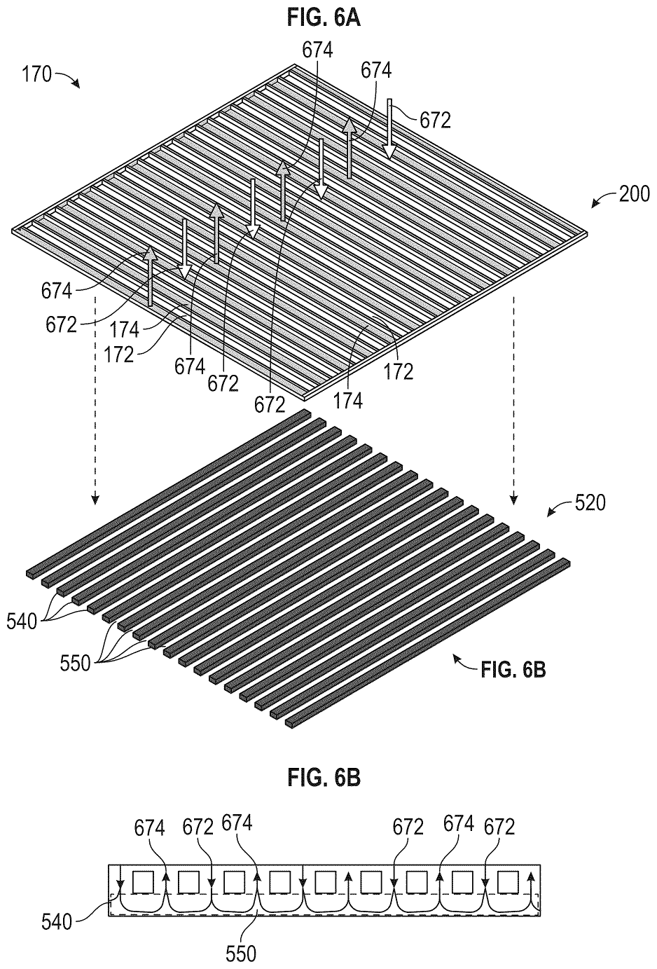

FIG. 5A shows an example finned plate 500 including a base plate 510 and a microchannel array 520 on the base plate 510, which may be arranged on an electronic component to be cooled. Thermal energy in the electronic component is absorbed by the microchannel array 520 and transferred to a cool coolant stream as it enters the microchannel array 500 where the thermal energy warms the coolant stream to generate the liquid discharge.

FIG. 5B is an expanded view of FIG. 5A showing a plurality of fins 540 of the microchannel array 520 that are connected to and extend from a surface of the base plate 510, adjacent ones of the fins 540 being spaced apart from each other to form a plurality of microchannels 550 between the fins 540, one of the microchannels 550 being between each adjacent two of the fins 540. The microchannels 550 are in fluid communication with an interior of the flow equalizing manifold, e.g., passages in final hierarchical level 170. The microchannels 550 may extend in a direction parallel to each other and perpendicular to a direction of extension of passages in final hierarchical level 170, but the present disclosure is not limited thereto.

The top boundary 560 of the finned plate 500 and a bottom boundary of the flow equalizing manifold may each independently have a planar outer surface opposite to each other. The planar outer surfaces may be substantially flat or level and are configured to reduce or prevent or reduce loss and/or ingress of liquid and/or vapor from the flow equalizing manifold. The bottom boundary may be on the final hierarchical level 170, but the present disclosure is not limited thereto. In some embodiments, the cooling apparatus may include an interface between the top boundary 560 and the bottom boundary and the interface may be substantially flat or level.

In one or more of embodiments, a bottom surface of the finned plate 500 may be geometrically flexible and configured to conform to a non-planar surface, an irregularly shaped surface, and any suitable combination thereof.

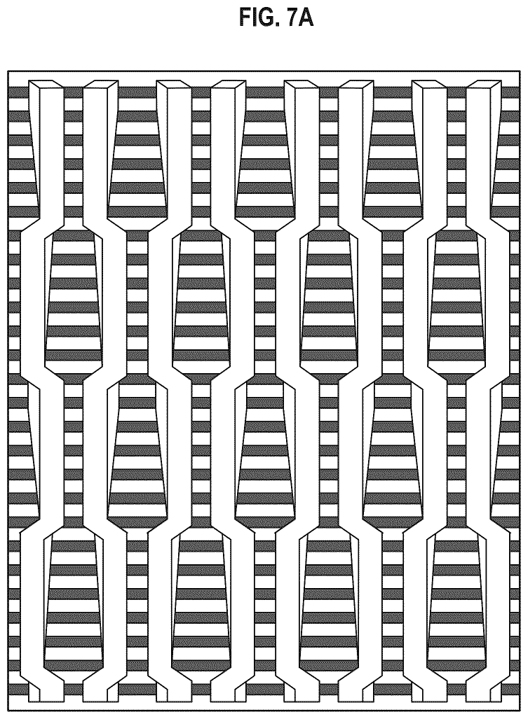

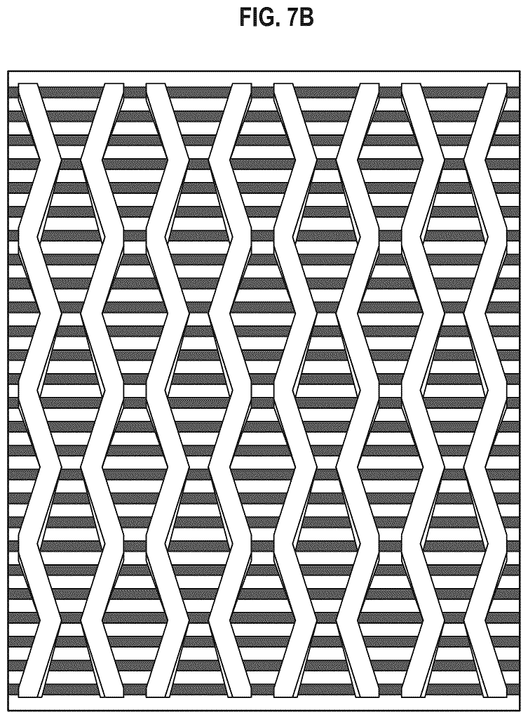

FIG. 6A shows passages 172, 174 of the final hierarchical level 170 extending perpendicular to the extension direction of the microchannels 550. Coolant streams 672 in HFD passages 172 are shown as downwardly pointing arrows and liquid discharge streams 674 in HFA passages 174 are shown as upwardly pointing arrows. FIG. 6B is a cross-sectional view of the interior of a microchannel 550 viewed from perspective “FIG. 6B” shown in FIG. 6A, and shows coolant streams 672 entering the microchannel 550 and a fin 540 is oriented lengthwise in the background. Curved arrows in FIG. 6B illustrate a typical flow path for coolant steams 672 that absorb heat (e.g., from base plate 510 and fins 540) and exit as warm liquid discharge streams 674. A width of the microchannels 550 (distance between two adjacent fins 540) may confine coolant streams 672 to a relatively short flow path before they reverse direction. The phrase “short flow path” as used herein, refers to the distance traveled by a coolant stream in a passage or microchannel. The curved arrows illustrate the reversal of flow within the microchannel 550, which may enhance heat absorption by the coolant stream and may minimize or reduce thermal resistance. As the coolant streams 672 absorb heat and the flow direction is reversed, they are transformed into warm liquid discharge streams 674 that are directed out of the microchannel array 520 and into the HFA passages 174 of the final hierarchical level 170.

In one or more embodiments, the width of the microchannels 550 may be at most about 500 μm.

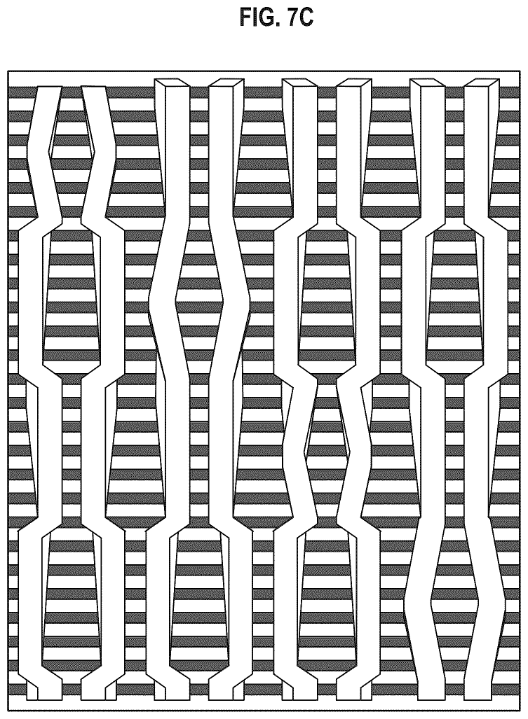

FIG. 7 shows polygonal fluid passages according to one or more embodiments of the present disclosure that include a tessellated pattern of hexagonal fluid passages, a tessellated pattern of tetragonal fluid passages, and a combined tessellated pattern of hexagonal and tetragonal fluid passages. The polygonal fluid passages may be included in a flow equalizing manifold according to the present disclosure, e.g., flow equalizing manifold 100, 800, 900 or 1000, as shown in FIGS. 1, 8, 9 and 10.

In some embodiments, the polygonal fluid passages may be included in a final hierarchical level and fluid may flow into that level near the center of the polygons where width is greatest. Some fluid may enter the microchannel array and the rest may pass laterally towards more narrow polygon regions which allows additional fluid to enter the microchannel array, thereby balancing flow conditions, because less cross sectional area is needed in a hierarchical level above the final level due to the fluid that passed into the microchannel array. Opposite behavior may occur in the outlet passages where the polygon is widest next to the outflow passage up to the final hierarchical level where the most fluid may be collected from the microchannels and the polygon width tapers away from this region. The taper may reduce pressure loss and improve flow uniformity to the microchannels.

### Flow Equalizing Manifolds 800, 900, 1000

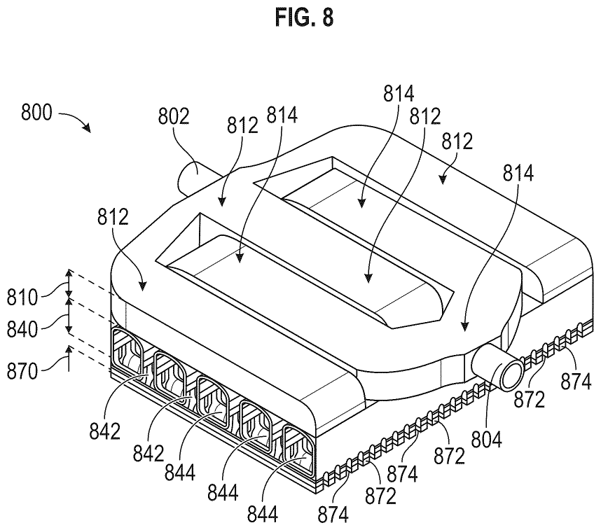

FIG. 8 shows flow equalizing manifold 800 according to one or more embodiments of the present disclosure including inlet 802, outlet 804, top level 810, top descending passages 812, top ascending passages 814, first hierarchical level 840, H1D passages 842, H1A passages 844, final hierarchical level 870, HFD passages 872, and HFA passages 874.

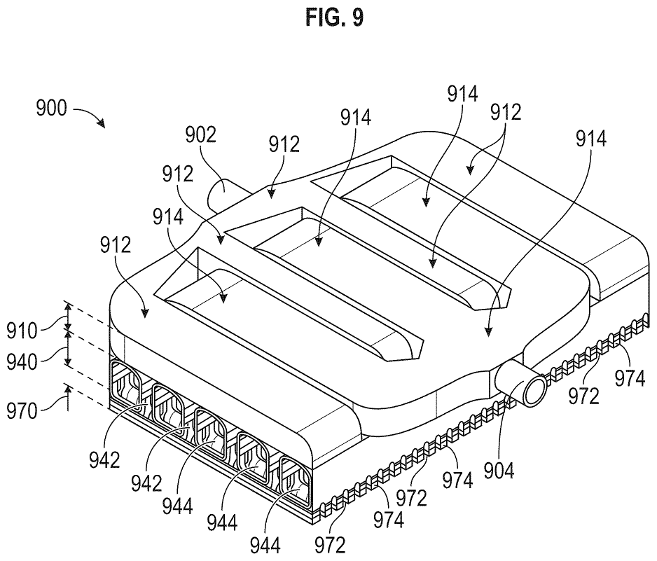

FIG. 9 shows flow equalizing manifold 900 according to one or more embodiments of the present disclosure including inlet 902, outlet 904, top level 910, top descending passages 912, top ascending passages 914, first hierarchical level 940, H1D passages 942, H1A passages 944, final hierarchical level 970, HFD passages 972, and HFA passages 974. The first and second ends of the top descending passages 912 are aligned with each other, and are offset from first and second ends, respectively, of the top ascending passages 914. The first and second ends of the top ascending passages 914 are aligned with each other, and are offset from first and second ends, respectively, of the top descending passages 912.

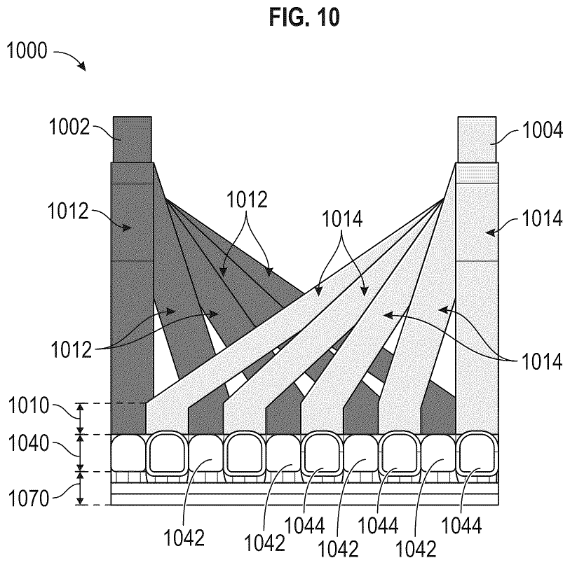

FIG. 10 shows flow equalizing manifold 1000 according to one or more embodiments of the present disclosure including inlet 1002, outlet 1004, top level 1010, top descending passages 1012, top ascending passages 1014, first hierarchical level 1040, H1D passages 1042, H1A passages 1044, final hierarchical level 1070 including HFD passages and HFA passages.

### Additional Features of Flow Equalizing Manifold

The flow equalizing manifold may include auxiliary features in sections of passages between two hierarchical levels, non-limiting examples of which include flow dividing ribs, wings, an array of posts, an array of tubes, a truss structure, fins extending only from one side, and steps.

The flow equalizing manifold may include filtration selected from among mesh screens, porous materials, helical structures, vortex structures, and replaceable cartridges.

### Microchannels

The microchannels may be in fluid communication with the HFD, the HFA, the HFAV, and/or the HFAL passages, and may extend in a direction parallel to each other and perpendicular to a direction of extension of the HFD, the HFA, the HFAV, and/or the HFAL passages.

In one or more of embodiments, a width of the microchannels may be about 1 μm to about 500 μm, about 5 μm to about 300 μm, or about 20 μm to about 120 μm. It is also understood that these ranges also include all sub-ranges and other ranges beginning and/or ending with any point within these ranges, for example, while the preceding range of about 20 μm to about 120 μm is disclosed, a range of, for example, about 40 μm to about 100 μm is also contemplated and included within the range. In one or more of embodiments, the finned plate may include about 50 to about 500 microchannels.

### Fins

In one or more of embodiments, the fins may include a thermally conductive material and may have a highest thermal conductivity axis with a conductivity of at least about 50 watt per meter degree K (W/m−K). In one or more of embodiments, the fins may include aluminum having a thermal conductivity of about 200 W/m−K, copper having a thermal conductivity of about 400 W/m−K, or a copper alloy having a thermal conductivity of about 350 Wm-K to about 400 W/m−K. In one or more of embodiments, the conductivity of the highest thermal conductivity axis of the fins may be about 400 W/m−K to about 3000 W/m−K, about 600 W/m−K to about 1500 W/m−K, or about 800 W/m−K to about 1200 W/m−K. It is also understood that these ranges also include all sub-ranges and other ranges beginning and/or ending with any point within these ranges, for example, while the preceding range of about 800 W/m−K to about 1200 W/m−K is disclosed, a range of, for example, about 900 W/m−K to about 1000 W/m−K is also contemplated and included within the range. The fins 240 may include a protective coating to reduce or prevent corrosion and the protective coating may include nickel, but the present disclosure is not limited thereto.

Aligned graphite has a thermal conductivity in a range of about 1000 W/m−K to about 1,500 W/m−K along its most thermally conductive axis (also referred to as its along-fin axis) compared with silicon, which has a thermal conductivity of about 100 W/m−K. Thus, aligned graphite enables higher fin efficiency (e.g., greater than about 50%) for high-aspect ratio fins (e.g., fins having a greater than 30:1 height to thickness ratio). In some embodiments, the fins may include aligned pyrolytic graphite having a thermal conductivity greater than 1000 W/m−K along the fin axis.

In one or more of embodiments, a thickness of the fins may be about 1 μm to about 500 μm, about 5 μm to about 300 μm, or about 20 μm to about 120 μm. It is also understood that these ranges also include all sub-ranges and other ranges beginning and/or ending with any point within these ranges, for example, while the preceding range of about 20 μm to about 120 μm is disclosed, a range of, for example, about 40 μm to about 100 μm is also contemplated and included within the range.

In one or more of embodiments, a height of the fins may be about 200 μm to about 5000 μm, about 400 μm to about 3,500 μm, or about 600 μm to about 1,800 μm. It is also understood that these ranges also include all sub-ranges and other ranges beginning and/or ending with any point within these ranges, for example, while the preceding range of about 600 μm to about 1,200 μm is disclosed, a range of, for example, about 900 μm to about 1000 μm is also contemplated and included within the range.

### Base Plate

The base plate has an optimum thickness to accommodate the stress caused if (e.g., when) connecting the finned plate 200 to the flow equalizing manifolds 100, 800, 900 and 1000. If (e.g., when) the base plate is too thin, the stresses may cause the microchannel arrays to bow and/or curve, which may increase thermal interface resistance between the finned plate and a heat source (e.g., an electronic component). If (e.g., when) the base plate is too thick, the added (unnecessary) material may increase the thermal resistance of solid conduction.

The base plate may include thermal stress mitigating materials that have coefficient of thermal expansion (CTE) matching to the heat source material (e.g., a silicon electronic component) with relatively high compliance. For example, the CTE of CuMo and copper impregnated graphite (POCO) are each similar to silicon and POCO also has a relatively high shear compliance. Thermally induced stress due to CTE mismatch may be lower in POCO than in CuMo. Non-limiting examples of materials suitable for the base plate include CuW, Cu-diamond, Cu—SiC, and Cu—AlN.

The base plate may include at least one metal or metal-containing compound having high thermal conductivity. In some embodiments, the base plate 210 may include aluminum, carbon, copper, gold, molybdenum, nitrogen, palladium, platinum, silicon, silver, tungsten, graphite, diamond, an alloy thereof, a compound thereof, and a (e.g., any suitable) combination thereof. The base plate 210 may be manufactured using skiving, related art machining (e.g., milling or sawing/cutting), or additive manufacturing (e.g., LBPF, SLS, ECAM, and/or the like), but the present disclosure is not limited thereto.

In one or more of embodiments, a thickness of the base plate may be about 10 μm to about 2000 μm, about 100 μm to about 1000 μm, or about 400 μm to about 600 μm. It is also understood that these ranges also include all sub-ranges and other ranges beginning and/or ending with any point within these ranges, for example, while the preceding range of about 250 μm to about 750 μm is disclosed, a range of, for example, about 300 μm to about 400 μm is also contemplated and included within the range.

In one or more of embodiments, a shear modulus of the base plate may be about 10 megapascal (MPa) to about 300 gigapascal (GPa), about 100 MPa to about 100 GPa, or about 1000 MPa to about 5 GPa. It is also understood that these ranges also include all sub-ranges and other ranges beginning and/or ending with any point within these ranges, for example, while the preceding range of about 100 MPa to about 100 GPa, is disclosed, a range of, for example, about 800 MPa to about 80 GPa is also contemplated and included within the range.

### Location of Vapor+Liquid Outlet

In one or more embodiments, the liquid outlet may be in the first hierarchical level, the second hierarchical level, or the final hierarchical level. At least one auxiliary liquid outlet may be located in the first, second, final, or a further hierarchical level. The auxiliary liquid outlet(s) may be in addition to the liquid outlet in the top level as described herein. In one or more embodiments, the auxiliary liquid outlet(s) may be primary (e.g., only) liquid outlet(s), such that the liquid outlet in the top level is effectively not included in (e.g., excluded from) the flow equalizing manifold. It will be appreciated, that locating primary liquid outlet(s) below the vapor outlet may facilitate separation and removal of the liquid discharge from the vapor discharge and enhance or increase the efficiency of the cooling apparatus.

The inlet and the outlets of the flow equalizing manifold may include a thermal isolation layer having a gas-filled cavity, an aerogel, or a low-conductivity polymer.

The flow equalizing manifold may include at least one flow control element including at least one valve, at least one variable orifice, and/or at least one deformable membrane configured to dynamically adjust flow distribution.

### Method of Making the Cooling Apparatus

According to one or more embodiments of the present disclosure, a method of making the cooling apparatus includes forming the flow equalizing manifold having the top, first hierarchical, and final hierarchical levels with inlet passages, outlet passages, descending passages, and ascending passages, and forming the finned plate having the microchannel array.

The method may include coupling the flow equalizing manifold to the finned plate. The method may include coupling the flow equalizing manifold to the finned plate across a top boundary of the finned plate and a bottom boundary of the flow equalizing manifold. The method may include coupling the flow equalizing manifold to the finned plate across an interface between the top boundary and the bottom boundary.

In some embodiments, the fins and base plate may be manufactured using the same method or the fins may be fabricated onto a base plate that was previously fabricated using a different method (e.g., additive fins on a conventionally machined base plate). Additional machining may be performed on the finned plate after the fins are formed (e.g., holes drilled, edges cut to shape).

The method may include a suitable additive manufacturing process (e.g., 3D printing), non-limiting examples of which include vat polymerization (e.g., stereolithography; digital light processing; scan, spin, and selectively photocure; substantially continuous liquid interface production), powder bed fusion (e.g., selective laser sintering, direct metal laser sintering, selective laser melting, selective heat sintering, multi-jet fusion), binder jetting (e.g., 3DP, ExOne, VoxelJet, desktop metal), material jetting (e.g., Polyjet, Smooth Curvatures Printing, Multijet Modeling, Projet), sheet lamination (e.g., laminated object manufacture, selective deposition lamination, ultrasonic additive manufacturing), material extrusion (e.g., fused filament fabrication, fused deposition modeling, direct ink write), directed energy deposition (e.g., laser metal deposition, laser energy net shaping, direct metal depositions, laser engineered net shaping), hybrids of multiple additive manufacturing methods, and/or hybrids of additive and subtractive manufacturing methods. Subtractive manufacturing may refer to, as some examples, machining or computer numerical control (CNC) machining. In one or more embodiments, the manifold may be fabricated utilizing a hybrid process combining laser powder bed fusion (LPBF) for structural features and electrochemical additive manufacturing (ECAM) for fine-resolution internal channels. This hybrid approach enables high-density microchannel integration with minimal post-processing.

One or more suitable post-processing treatments may be used to remove unwanted material after additive manufacturing and provide for a better interior surface finish, e.g., electrochemical etching, flushing with fluid and abrasive media, vibration, or a combination thereof. The flow equalizing manifold and the finned plate may be fabricated in two or more parts and then bonded or gasketed together as described in more detail herein. The flow equalizing manifold and the finned plate may be manufactured as a single piece using additive manufacturing (e.g. LBPF, SLS, ECAM, and/or the like) methods to obtain single-piece construction.

According to one or more embodiments, the flow equalizing manifold and the finned plate may be modular components and may be removably coupled or connected to each other.

Performance efficiency of the cooling apparatus may be improved by minimizing or reducing distances between inflow and outflow regions at an interface of the flow equalizing manifold and the finned plate. The flow equalizing manifold may have single walls that are non-thermally conductive or may have double walls including two solid layers coupled only at the top and/or bottom and nowhere in between to provide a substantially continuous region of air separating the two layers. The single or double walls and the region of air are of minimum thickness as allowed by the additive material and its manufacturing process. These strategies ensure that the distance traveled by a coolant in a fluid passage (e.g., between exiting the manifold as cold inflow and reentering the manifold as hot outflow) is a short flow path and is minimized (reduced) to minimize (reduce) pressure drop and improve heat transfer. Minimizing wall and gap thicknesses provides short flow paths are as short as possible, which minimizes (reduces) frictional pressure loss and maximizes heat transfer due to maximization of developing regions.

The flow equalizing manifold may be or include a polymer, resin, metals, ceramics, glasses, composites, and/or a (e.g., any suitable) combination thereof. A low-thermal conductivity, high-temperature resin (e.g., with heat deflection temperature specification determined by application temperature boundary conditions) may be used in additive manufacture of the manifold to thermally isolate the cold inflow from the warm outflow (prevents preheating and preserves maximal temperature difference).

The double wall construction may be used in the flow equalizing manifold and may be manufactured from high thermal conductivity materials like metals, such that everywhere the cold inflow and hot outflow are oriented in adjacent cavities, the two are separated by a gap region with a gas state (e.g., air), for example cold inflow/metal manifold wall/air/metal manifold wall/hot outflow. Regions between the two walls may include air, an inert gas, a noble gas, aerogel, porous foam insulation, mechanical spacer features (e.g., periodic posts or spars), hollow microspheres (e.g. hollow glass microspheres), and/or a (e.g., any suitable) combination thereof. In some embodiments, the air gap (or gap region) may be filled with a low-conductivity gas such as xenon or krypton to further reduce thermal bridging. Alternatively, in one or more embodiments, the gap may be evacuated to create a vacuum-insulated barrier.

### Additional Features of Cooling Apparatus

In one or more embodiments, a cooling apparatus of the present disclosure may include an interface between the top boundary of the finned plate and a bottom boundary of the flow equalizing manifold. The bottom boundary may be on the final hierarchical level, but the present disclosure is not limited thereto.

According to one or more embodiments of the present disclosure, the cooling apparatus may include a compression gasket and each of the finned plate and the flow equalizing manifold may have a sealing groove. The dimensions of the sealing groove may be iteratively improved or optimized to provide sufficient sealing while also minimizing or reducing gasket compression-induced stresses, e.g., on the fins and/or the finned plate. The compression gasket may be an o-ring gasket and the sealing groove may be a recessed groove suitable for use with the o-ring gasket but the present disclosure is not limited thereto.

The compression gasket (e.g., o-ring gasket) may be or include rubber, silicone, other elastomeric materials, and/or a (e.g., any suitable) combination thereof. In some embodiments, the compression gasket may be a flat gasket or may be a formed-in-place gasket.

The finned plate may be coupled to the flow equalizing manifold with a bond interface such as a brazed bond, a soldered bond, an adhesive (e.g., epoxy) bond, a fusion bond, and/or a (e.g., any suitable) combination thereof. In one or more embodiments, the finned plate and the flow equalizing manifold may be fabricated as a single component and include a compression gasket and/or bond interface.

The cooling apparatus may include an air gap between the finned plate and the flow equalizing manifold. Differences in thermal expansion characteristics of the two components may result in uneven expansion of the two components that results in lateral stress, bending, delamination, and/or the like. The air gap enables the finned plate and the flow equalizing manifold to expand independently, thereby reducing mechanical stress.

The air gap may be substantially continuous or segmented, and may be formed by spacers, ridges, or molded features in the manifold or bracket. In some embodiments, the air gap may be filled with a compliant material such as silicone foam, elastomeric foam, or inert gas to provide vibration damping while still allowing thermal expansion.

The flow equalizing manifold may include flow dividers configured to partition an input flow into flow stream sections. The flow dividers may be oriented vertically and/or horizontally and may be spaced apart at a distance that is regular, area preserving, or flowrate preserving. The flow dividers may be added to primary passages imposing secondary passages within primary passages to further discretize the flow. The flow dividers may include the same material from which the flow equalizing manifold is manufactured and may be flat and/or fin-shaped.

In one or more embodiments, each of the flow stream sections may have a substantially equal flowrate.

The flow dividers may be configured to modulate a Reynolds number of the flow stream sections. In some embodiments, the flow stream sections have a laminar flow. In one or more embodiments, the flow dividers are shaped to induce secondary flow structures that enhance convective heat transfer while maintaining laminar flow conditions.

In some embodiments, a space between two adjacent of the flow dividers may be an integral of a Poiseuille distribution of the flow stream.

The flow equalizing manifold may include internal flow balancing (e.g., flow shaping) structures having shapes that streamline fluid flow, reduce vortex formation, promote laminar flow, and/or reduce turbulence. In some embodiments, the flow balancing (e.g., flow shaping) structures may be at least one selected from among airfoil-shaped vanes (e.g., airfoils or hydrofoils), flow dividing ribs, wing-shaped vanes, arrays of posts, arrays of tubes, truss structures, fins, curved fins, streamlined baffles and steps. In some embodiments, the flow balancing (e.g., flow shaping) structures may reduce pressure drop, improve flow uniformity, and/or enhance thermal performance.

In some embodiments, the flow balancing (e.g., flow shaping) structures may be positioned to align with the direction of fluid flow. For example, the flow balancing (e.g., flow shaping) structures may not be fixed in place and may rotate to align with the direction of fluid flow. In some embodiments, the flow balancing structures (e.g., flow shaping) may be additively manufactured as part of the manifold body.

At least one of the inlet passages, outlet passages, TD passages, the H1D passages, the HFD passages, the TA passages, the H1A passages, the HFA passages, the TAL passages, the H1AL passages, and the HFAL passages may include the flow balancing (e.g., flow shaping) structures.

### Method of Operating the Cooling Apparatus

According to one or more embodiments, a method of operating the cooling apparatus of the present disclosure includes introducing the liquid inflows including a cool fluid to the inlet passages; flowing the cool fluid into the TD passages to provide liquid streams in the TD regions and regulating the flow conditions of the liquid streams in the TD regions; flowing the cool fluid into the HFD passages to provide the FDL streams and regulating the flow conditions of the FDL streams, the FDL streams including the cool fluid; flowing the FDL streams into the microchannel array to provide microchannel flow streams; regulating the flow conditions of the microchannel flow streams having microchannel flow conditions; transferring energy (e.g., thermal energy, heat) to the microchannel flow streams to provide the FAL streams, the FAL streams including a warm fluid; and flowing the FAL streams into the HFA passages and regulating the flow conditions of the FAL streams, the FAL streams including the warm fluid.

In one or more embodiments, regulating of the flow conditions of the FDL, FDL, and microchannel flow streams may include passively regulating with the heights of the tapered ceilings according to Bernoulli's principle.

According to one or more embodiments, a method of operating the cooling apparatus of the present disclosure includes introducing the liquid inflow including a cool fluid to the inlet passage; flowing the FDL streams into the HFD polygonal passages and regulating the first flow conditions of the FDL streams, the FDL streams including the cool fluid; flowing the FDL streams into the microchannel array to provide microchannel flow streams having microchannel flow conditions; regulating the microchannel flow conditions; transferring energy (e.g., thermal energy, heat) to the microchannel flow streams to provide the FAL streams, the FAL streams including a warm fluid; and flowing the FAL streams into the HFA polygonal passages and regulating the second flow conditions of the FAL streams, the FAL streams including the warm fluid.

In one or more embodiments, regulating of the first flow conditions, the second flow conditions, and the microchannel flow conditions may include passively regulating with the polygonal fluid passages according to Bernoulli's principle.

According to one or more embodiments, a method of operating the cooling apparatus of the present disclosure includes introducing liquid coolant to the at least one inlet passage; directing the liquid coolant through the TD and H1D passages to the HFD passages and into the microchannel array; generating vapor in the microchannel array; passing vapor from the microchannel array into the HFAV passages and to the vapor outlet; passing liquid from the microchannel array into the HFAL passages and to the liquid outlet; and maintaining a liquid fraction within the microchannel array during operation by routing vapor through the HFAV passages to reduce dry-out and flow instabilities.

### Cooling Systems

One or more aspects of embodiments of the present disclosure are directed toward a cooling system including at least one cooling apparatus including a finned plate and a flow equalizing manifold as described herein, at least one pump configured to circulate a coolant, and at least one heat exchanger in fluid communication with the flow equalizing manifold of the cooling apparatus.

The cooling system may include an electronic component and a cooling apparatus as described herein on the electronic component. The electronic component may include a semiconductor chip and/or an integrated circuit but the present disclosure in not limited thereto.

The cooling system may include a condenser configured to convert vapor collected at the vapor outlet to liquid. In one or more embodiments, the cooling system is configured for the lowering of pressure within the cooling apparatus to facilitate phase change (e.g., evaporation) of the liquid coolant stream to a vapor at reduced temperatures. For example, a partial vacuum may be applied to the internal space within the cooling apparatus to lower the vapor pressure (e.g., apparent boiling temperature) of the liquid coolant stream.

The cooling system may include a return loop for the vapor outlet to the liquid inlet, the return loop including a condenser and a pump.

One or more aspects of embodiments of the present disclosure are directed toward a systems-level integrated cooling system including a plurality of cooling apparatuses each as described herein, a shared coolant distributor configured to supply a coolant to each of the plurality of cooling apparatus, a controller configured to monitor and adjust coolant flow rates to each of the plurality of cooling apparatuses based on thermal load, and a heat exchanger in fluid communication with the shared coolant distributor.

In some embodiments, the coolant streams and/or liquid discharge in the cooling apparatus, finned plate, and/or flow equalizing manifold and/or between the cooling apparatus and the heat exchanger may have a laminar flow or a non-laminar flow.

One or more aspects of embodiments of the present disclosure are directed toward a data center including a plurality of electronic components, at least one cooling system according to present disclosure, where the plurality of cooling apparatuses are on the plurality of electronic components.

For example, in one or more embodiments, the disclosed cooling architecture is desired or suitable or enhanced for deployment in AI data centers and other high-density computing environments where thermal uniformity and scalability are critical. The hierarchical manifold described herein may be integrated with modular cooling blocks that may be arranged in arrays across multiple server boards or racks. This modular approach enables rapid replacement and maintenance while preserving substantially continuous operation, and supports system-level orchestration of coolant distribution through shared manifolding and centralized control loops.

The present disclosure further contemplates integration strategies that leverage hierarchical manifolding to reduce or minimize or reduce pressure drop across large-scale coolant networks. For example, top-level passages may interface with facility-level coolant distributors, while final hierarchical levels couple directly to microchannel arrays on individual chips. This arrangement facilitates predictable flow partitioning and phase management across thousands of electronic components, thereby reducing thermal hotspots and improving overall energy efficiency. These features are, e.g., for coordinated operation of multiple cooling apparatuses within a unified cooling system. In some embodiments, rather than maintain a uniform flow throughout the entire manifold, the geometric features of the flow equalizing manifold informed by Bernoulli's principle may bias flow. For example, the amount of flow may be biased to deliver more only where needed to reduce convective resistance (e.g., hotspots), thereby reducing the overall flow rate and increasing efficiency.

Terms such as “substantially,” “about,” and “~” are utilized as terms of approximation and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all sub-ranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

While the present disclosure has been described in connection with certain example embodiments, it is to be understood that the present disclosure is not limited to the disclosed embodiments, but, on the contrary, is intended to cover one or more suitable modifications and equivalent arrangements included within the spirit and scope of the claims, and equivalents thereof.

The annotations used in this specification and FIGS. 1-4, 5A, 5B, 6A, 6B, and 7-10 are listed hereafter.
FAL: final ascending liquid
FDL: final descending liquid
H1A: first hierarchical ascending
H1AL: first hierarchical ascending liquid
H1AV: first hierarchical ascending vapor
H1D: first hierarchical descending
H2A: second hierarchical ascending
H2D: second hierarchical descending
HFA: final hierarchical ascending
HFAL: final hierarchical ascending liquid
HFAV: final hierarchical ascending vapor
HFD: final hierarchical descending
H-IN: intake height
H-INM: average stepped ceiling height of TD passage
H-OT: output height
H-OTM: average stepped ceiling height of TA passage
TA: top ascending
TAL: top ascending liquid
TAV: top ascending vapor
TD: top descending
XA: number of H1A passages
XD: number of H1D passages
1DL: first descending liquid
1AL: first ascending liquid
10: cooling apparatus
100: flow equalizing manifold
102: inlet passage
104: outlet passage
110: top level
112: top descending passage
114: top ascending passage
140: first hierarchical level
142: H1D passage
142a-d: H1D passage
144: H1A passage
144a-e: H1A passage
170: final hierarchical level
172: HFD passage
174: HFA passage
200: finned plate
342a-d: 1DL stream
344a-e: 1AL stream
412: linear ceiling of TD passage
414: linear ceiling of TA passage
422: angle LCA
424: angle LCA
432: BSD distance
434: BSA distance
442: linear ceiling height
444: linear ceiling height
500: finned plate
510: base plate
520: microchannel array
540: fin
550: microchannel
560: top boundary
672: coolant stream
674: discharge stream
800: flow equalizing manifold
802: inlet
804: outlet
810: top level
812: top descending passage
814: top ascending passage
840: first hierarchical level
842: H1D passage
844: H1A passage
870: final hierarchical level
872: HFD passage
874: HFA passage
900: flow equalizing manifold
902: inlet
904: outlet
910: top level
912: top descending passage
914: top ascending passage
940: first hierarchical level
942: H1D passage
944: H1A passage
970: final hierarchical level
972: HFD passage
974: HFA passage
1000: flow equalizing manifold
1002: inlet
1004: outlet
1010: top level
1012: top descending passage
1014: top ascending passage
1040: first hierarchical level
1042: H1D passage
1044: H1A passage
1070: final hierarchical level

What is claimed is:

1. A flow manifold for thermal management comprising:
a primary plenum configured to receive or discharge a coolant;
a plurality of hierarchical flow levels comprising:
a top level having at least one inlet and a set of descending passages and at least one outlet and a set of ascending passages;
at least one intermediate level having branching passages in fluid communication with the top level; and
a final level comprising a tessellated array of hexagonal flow units and diamond-shaped flow units arranged between or adjacent to the hexagonal flow units,
wherein the diamond-shaped flow units comprise internal constrictions and diverging channels dimensioned to split or merge fluid in a set ratio, and
wherein a thickness or cross-sectional area of at least one of the hexagonal or diamond-shaped flow units varies laterally such that local cross-sectional area along a prescribed streamline varies according to Bernoulli's principle to maintain substantially constant local flow velocity and passively regulate flow distribution.

2. A flow equalizing manifold comprising:
a top level comprising:
at least one inlet configured for a liquid inflow and top descending (TD) passages in fluid communication with the inlet; and
at least one outlet configured for a liquid discharge and top ascending (TA) passages in fluid communication with the outlet,
a first hierarchical level comprising:
first hierarchical descending (H1D) passages in fluid communication with the TD passages and having first descending liquid (1DL) streams; and
first hierarchical ascending (H1A) passages in fluid communication with the TA passages and having first ascending liquid (1AL) streams,
the H1D passages configured for the 1DL streams and the H1A passages configured for the 1AL streams,
a final hierarchical level comprising:
polygonal fluid passages comprising final hierarchical descending (HFD) polygonal passages and final hierarchical ascending (HFA) polygonal passages,
the HFD polygonal passages in fluid communication with the H1D passages and having final descending liquid (FDL) streams, the HFD polygonal passages configured to provide first flow conditions to the FDL streams; and
the HFA polygonal passages in fluid communication with the H1A passages and having final ascending liquid (FAL) streams, the HFA polygonal passages configured to provide second flow conditions to the FAL streams,
wherein the first flow conditions and the second flow conditions comprise pressure and velocity.

3. The flow equalizing manifold of claim 2, wherein the polygonal fluid passages are configured to passively regulate the first flow conditions and the second flow conditions according to Bernoulli's principle, and
the first flow conditions are substantially equal to or different than the second flow conditions.

4. The flow equalizing manifold of claim 2, wherein the polygonal fluid passages comprise hexagonal fluid passages, tetragonal fluid passages, and any suitable combination thereof.

5. The flow equalizing manifold of claim 4, wherein the polygonal fluid passages comprise a repeating configuration of the hexagonal fluid passages.

6. The flow equalizing manifold of claim 5, wherein the repeating configuration of the hexagonal fluid passages further comprises tetragonal fluid passages, wherein the tetragonal fluid passages are between two of the hexagonal fluid passages, at an inlet of a polygonal fluid passage, at an outlet of a polygonal fluid passage, and any suitable combination thereof.

7. The flow equalizing manifold of claim 4, wherein at least one of the hexagonal fluid passages and the tetragonal fluid passages comprise flow channeling, flow guides, flow-splitting nodes, flow-merging nodes, and any suitable combination thereof,
the flow channeling comprising flow constrictions, flow divergences, and any suitable combination thereof,
the flow guides comprising posts, vanes, trusses, and any suitable combination thereof, and
the flow-splitting nodes and the flow-merging nodes comprise flow ratios, the flow ratios independently selected from among 1:2 to 1:10 and 10:1 to 2:1.

8. The flow equalizing manifold of claim 4, wherein at least one of the hexagonal fluid passages and the tetragonal fluid passages comprise flexible flow passages.

9. The flow equalizing manifold of claim 2, wherein
the H1D passages are greater in number than the TD passages,
the H1A passages are greater in number than the TA passages,
the HFD polygonal passages are greater in number than the H1D passages,
the HFA polygonal passages are greater in number than the H1A passages,
the TD passages and the TA passages extend in an initial direction,
the H1D passages and the H1A passages extend in a first direction, the first direction substantially perpendicular to and crossing the initial direction, and
the HFD polygonal passages and the HFA polygonal passages extend in a final direction, the final direction substantially the same as the initial direction.

10. The flow equalizing manifold of claim 9, further comprising at least one added hierarchical level.

11. The flow equalizing manifold of claim 2, wherein the flow equalizing manifold is additively manufactured.

12. A cooling apparatus comprising the flow equalizing manifold of claim 2 and a finned plate, wherein
the final hierarchical level further comprises a bottom boundary,
the finned plate comprises a base plate, a microchannel array, and a top boundary, the top boundary being opposite to the bottom boundary, and
each of the bottom boundary and the top boundary have a planar outer surface.

13. The cooling apparatus of claim 12, wherein the microchannel array comprises fins and microchannels,
the fins being connected to and extending from a surface of the base plate, each one of the microchannels being between each adjacent two of the fins,
the microchannels being in fluid communication with the FDL streams and the FAL streams, and extending in a direction parallel to each other and perpendicular to the final direction of the HFD polygonal passages and the HFA polygonal passages.

14. The cooling apparatus of claim 12, wherein a bottom surface of the finned plate is geometrically flexible and configured to conform to a non-planar surface, an irregularly shaped surface, and any suitable combination thereof.

15. The cooling apparatus of claim 12, wherein the flow equalizing manifold and the finned plate are modular and removably coupled, and independently configured for a coolant fluid comprising a one-phase fluid being substantially vapor-free or a two-phase fluid being a liquid-vapor mixture.

16. A method of operating the cooling apparatus of claim 12, the method comprising:
introducing the liquid inflow comprising a cool fluid to the inlet;
flowing the FDL streams into the HFD polygonal passages and regulating the first flow conditions of the FDL streams, the FDL streams comprising the cool fluid;
flowing the FDL streams into the microchannel array to provide microchannel flow streams having microchannel flow conditions;
regulating the microchannel flow conditions;
transferring energy to the microchannel flow streams to provide the FAL streams, the FAL streams comprising a warm fluid; and
flowing the FAL streams into the HFA polygonal passages and regulating the second flow conditions of the FAL streams, the FAL streams comprising the warm fluid.

17. The method of claim 16, wherein the regulating of the first flow conditions, the second flow conditions, and the microchannel flow conditions comprises passively regulating with the polygonal fluid passages according to Bernoulli's principle.

18. A method of making the cooling apparatus of claim 12, the method comprising:
forming the flow equalizing manifold having the top, first hierarchical, and final hierarchical levels with descending passages and ascending passages;
forming the finned plate having the microchannel array; and
coupling the flow equalizing manifold to the finned plate.

19. A cooling system comprising:
at least one cooling apparatus comprising the cooling apparatus according to claim 12;
at least one pump configured to circulate a coolant;
at least one heat exchanger in fluid communication with the flow equalizing manifold of the cooling apparatus;
an electronic component, the cooling apparatus on the electronic component; and
a heat exchanger in fluid communication with the flow equalizing manifold of the cooling apparatus.

20. A data center comprising:
a plurality of electronic components; and
at least one cooling system comprising the cooling system according to claim 19;
wherein the plurality of cooling apparatuses are on the plurality of electronic components.
